(19) United States
(12) Patent Application Publication
(10) Pub. No.: US 2026/0282998 A1
(43) Pub. Date: Sep. 17, 2026

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: Cheonbae KIM, Suwon-si (KR); Woochoel NOH, Suwon-si (KR)

(73) Assignee: SAMSUNG ELECTRONICS CO., LTD., Suwon-si (KR)

(21) Appl. No.: 19/421,627

(22) Filed: Dec. 16, 2025

(30) Foreign Application Priority Data
Mar. 17, 2025 (KR) 10-2025-0034141

(51) Int. Cl. H10W 72/90; H10B 80/00; H10W 72/00; H10W 90/00; H10W 90/20

(52) U.S. Cl. CPC H10W 72/963; H10B 80/00; H10W 72/01935; H10W 90/20; H10W 90/792

(57) ABSTRACT

Provided is a semiconductor device including a semiconductor structure including a semiconductor substrate and a semiconductor element layer, a wiring structure on the semiconductor structure, a bonding dielectric layer on the wiring structure, a connection pad penetrating the bonding dielectric layer from a top surface of the bonding dielectric layer in a downward direction and having sidewalls surrounded by the bonding dielectric layer, and a dummy pad penetrating at least a portion of the bonding dielectric layer from the top surface of the bonding dielectric layer in the downward direction and having sidewalls surrounded by the bonding dielectric layer, wherein a bottom surface of the dummy pad is at a higher vertical level than a bottom surface of the connection pad, and the bottom surface of the dummy pad includes a plurality of surfaces at different vertical levels.

### CROSS-REFERENCE TO RELATED APPLICATION

This application is based on and claims priority under 35 U.S.C. § 119 to Korean Patent Application No. 10-2025-0034141, filed on March 17, 2025, in the Korean Intellectual Property Office, the disclosure of which is incorporated herein by reference in its entirety.

### BACKGROUND

### 1. Field

The disclosure relates to a semiconductor device and a method of manufacturing the semiconductor device, and more particularly, to a semiconductor device including a bonding pad.

### 2. Description of the Related Art

As one of the methods of improving integration density of a semiconductor device, a semiconductor device in which a plurality of stacked structures are bonded by using a hybrid bonding method has been proposed. The hybrid bonding refers to a technique for vertically bonding an upper stacked structure and a lower stacked structure. The hybrid bonding may include bonding between bonding dielectric layers (for example, bonding between an upper bonding dielectric layer and a lower bonding dielectric layer) and bonding between metal pads (for example, bonding between an upper metal pad and a lower metal pad).

### SUMMARY

The disclosure provides a semiconductor device including a dummy pad having an exposed area identical to an exposed area of a connection pad, while being electrically isolated from wiring patterns of a wiring structure.

However, the disclosure is not limited to the above-mentioned, and other aspects will be readily understood by those skilled in the art from the following description.

According to an aspect of the disclosure, there is provided a semiconductor device including a semiconductor structure including a semiconductor substrate and a semiconductor element layer, a wiring structure on the semiconductor structure, a bonding dielectric layer on the wiring structure, a connection pad penetrating the bonding dielectric layer from a top surface of the bonding dielectric layer in a downward direction and having sidewalls surrounded by the bonding dielectric layer, and a dummy pad penetrating at least a portion of the bonding dielectric layer from the top surface of the bonding dielectric layer in the downward direction and having sidewalls surrounded by the bonding dielectric layer, wherein a bottom surface of the dummy pad may be at a higher vertical level than a bottom surface of the connection pad, and the bottom surface of the dummy pad may include a plurality of surfaces at different vertical levels.

According to another aspect of the disclosure, there is provided a semiconductor device including a semiconductor structure including a semiconductor substrate and a semiconductor element layer, a wiring structure under the semiconductor structure, a bonding dielectric layer under the wiring structure, a connection pad penetrating the bonding dielectric layer from a bottom surface of the bonding dielectric layer in an upward direction and having sidewalls surrounded by the bonding dielectric layer, and a dummy pad penetrating at least a portion of the bonding dielectric layer from the bottom surface of the bonding dielectric layer in the upward direction and having sidewalls surrounded by the bonding dielectric layer, wherein a top surface of the dummy pad may be at a vertical level lower than a top surface of the connection pad, and the top surface of the dummy pad may include a plurality of surfaces at different vertical levels.

According to another aspect of the disclosure, there is provided a semiconductor device including a plurality of stacked structures stacked in a vertical direction and including a first stacked structure and a second stacked structure disposed on the first stacked structure, wherein an upper structure of the first stacked structure may include a first bonding dielectric layer, a first connection pad penetrating the first bonding dielectric layer in a downward direction from a top surface of the first bonding dielectric layer, and a first dummy pad penetrating at least a portion of the first bonding dielectric layer in the downward direction from the top surface of the first bonding dielectric layer, wherein a lower structure of the second stacked structure may include a second bonding dielectric layer, a second connection pad penetrating the second bonding dielectric layer in an upward direction from a bottom surface of the second bonding dielectric layer and disposed on the first connection pad, and a second dummy pad penetrating at least a portion of the second bonding dielectric layer in the upward direction from the bottom surface of the second bonding dielectric layer and disposed on the first dummy pad, wherein at least one of a bottom surface of the first dummy pad and a top surface of the second dummy pad may include an embossed structure, and the embossed structure may include a plurality of surfaces arranged at different vertical levels.

According to another aspect of the disclosure, there is provided a method of manufacturing a semiconductor device, the method including forming a wiring structure on a semiconductor structure including a semiconductor substrate and a semiconductor element layer, the wiring structure including an uppermost wiring pattern and a wiring dielectric layer surrounding the uppermost wiring pattern, forming a bonding dielectric layer on the wiring structure, forming a dummy opening and a connection opening penetrating the bonding dielectric layer in a vertical direction, and forming a dummy pad filling the dummy opening and a connection pad filling the connection opening, wherein the dummy opening may expose the wiring dielectric layer and the bonding dielectric layer, and the connection opening may expose the bonding dielectric layer, the wiring dielectric layer, and the uppermost wiring pattern. In some embodiments, a surface of the wiring dielectric layer that is exposed upward by the dummy opening may include a lowest surface and a raised surface, and the raised surface may protrude from the lowest surface in the upward direction. In some embodiments, a surface of the bonding dielectric layer that is exposed upward by the dummy opening may include a raised surface, the raised surface may protrude from a vertical level of the bottom surface of the bonding dielectric layer in the upward direction, and the raised surface may form a continuous surface with the surface of the wiring dielectric layer that is exposed upward by the dummy opening. In some embodiments, the forming of the dummy opening and the connection opening may include forming a patterned photoresist layer on the bonding dielectric layer, and performing an etching process by using the patterned photoresist layer as an etching mask, and the patterned photoresist layer may include a fine photoresist pattern structure disposed in a dummy region. In some embodiments, the forming of the patterned photoresist layer may include forming a photoresist layer on the bonding dielectric layer and performing exposure and development on the photoresist layer to remove the photoresist layer in a connection region and to form the fine photoresist pattern structure in the dummy region. In some embodiments, a first exposed area of the bonding dielectric layer in the dummy region may be smaller than a second exposed area of the bonding dielectric layer in the connection region, a first outer boundary of the bonding dielectric layer in the dummy region may be the same as a second outer boundary of the bonding dielectric layer in the connection region, the first exposed area in the dummy region may be an area of the bonding dielectric layer that is exposed upward by the patterned photoresist layer, the second exposed area in the connection region may be an area of the bonding dielectric layer that is exposed upward by the patterned photoresist layer, the first outer boundary in the dummy region may be an outer boundary of the bonding dielectric layer that is exposed upward by the patterned photoresist layer, and the second outer boundary in the connection region may be an outer boundary of the bonding dielectric layer that is exposed upward by the patterned photoresist layer. In some embodiments, the fine photoresist pattern structure may include a plurality of photoresist bars protruding from the top surface of the bonding dielectric layer in the upward direction, and each of the plurality of photoresist bars may be spaced apart from one another in a horizontal direction. In some embodiments, each of the plurality of photoresist bars may extend in a first horizontal direction of the horizontal direction, and each of the plurality of photoresist bars may be spaced apart from one another in a second horizontal direction perpendicular to the first horizontal direction. In some embodiments, the plurality of photoresist bars may be arranged mirror-symmetrically with respect to a centerline in the horizontal direction that bisects the dummy region. In some embodiments, the performing of the etching process may include performing a first etching process by using the patterned photoresist layer as an etching mask and performing a second etching process by using a remaining photoresist layer as an etching mask, and the remaining photoresist layer may be a photoresist layer in which the fine photoresist pattern structure has been removed from the patterned photoresist layer.

### BRIEF DESCRIPTION OF DRAWINGS

Embodiments will be more clearly understood from the following detailed description taken in conjunction with the accompanying drawings in which:

FIG. 1 is a perspective view of a semiconductor device according to an embodiment;

FIG. 2 is a cross-sectional view of a semiconductor device according to an embodiment;

FIGS. 3A, 3B, and 3C are cross-sectional views of a semiconductor device according to an embodiment;

FIG. 4 is a cross-sectional view of a semiconductor device according to an embodiment;

FIGS. 5A and 5B are cross-sectional views of a semiconductor device according to an embodiment;

FIG. 6 is a cross-sectional view of a semiconductor device according to an embodiment;

FIG. 7 is a cross-sectional view of a semiconductor device according to an embodiment;

FIG. 8 is a perspective view of a semiconductor device according to an embodiment;

FIG. 9 is a cross-sectional view of a semiconductor device according to an embodiment;

FIG. 10 is a cross-sectional view of a semiconductor device according to an embodiment;

FIGS. 11, 12, 13A, 13B, 13C, 13D, 14, 15, and 16 are views for illustrating a method of manufacturing a semiconductor device according to an embodiment; and

FIGS. 17A, 17B, and 17C are cross-sectional views for illustrating a method of performing an etching process according to an embodiment.

### DETAILED DESCRIPTION

Hereinafter, embodiments will be described in detail with reference to the accompanying drawings. In the drawings, like reference characters denote like elements, and redundant descriptions thereof will be omitted.

In the drawings, the sizes, thicknesses, ratios, and dimensions of the elements may be exaggerated for ease of description and for clarity. Like reference numbers and reference characters refer to like elements throughout. The term “size” may include includes a length, a width, a thickness, an area, etc.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

In the specification, a horizontal direction may include a first horizontal direction (e.g., x-axis direction) and a second horizontal direction (e.g., y-axis direction) that intersect each other. A direction intersecting the first horizontal direction (e.g., x-axis direction) and the second horizontal direction (e.g., y-axis direction) may be referred to as a vertical direction (e.g., z-axis direction). In the specification, a vertical level may be referred to as a height level along the vertical direction (e.g., z-axis direction) of a given structure. Hereinafter, embodiments will be clearly and specifically described so that those skilled in the art may readily carry out the disclosure.

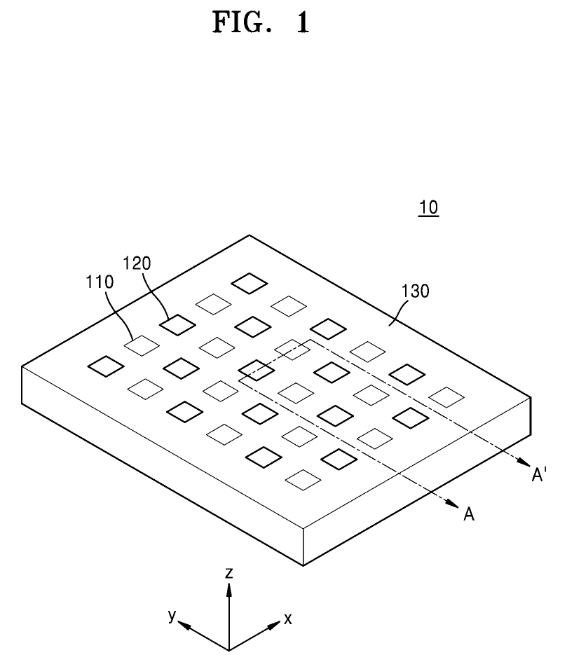

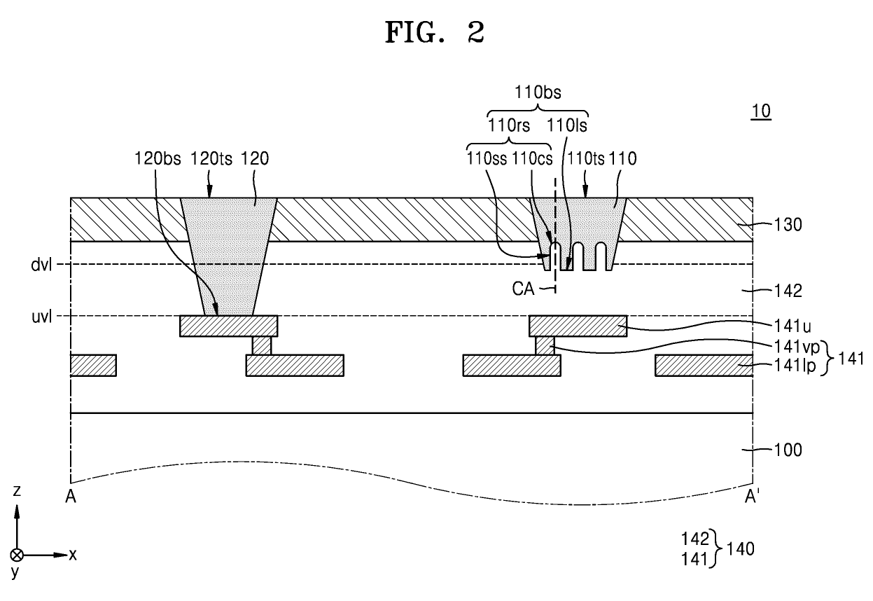

FIG. 1 is a perspective view of a semiconductor device 10 according to an embodiment. FIG. 2 is a cross-sectional view of the semiconductor device 10 according to the embodiment. FIG. 2 is a vertical cross-sectional view taken vertically along a horizontal line (e.g., a line A–A′) dividing a top surface 110ts of an upper dummy pad 110.

Referring to FIG. 1, the semiconductor device 10 may include the upper dummy pad 110, an upper connection pad 120, and an upper bonding dielectric layer 130. The upper bonding dielectric layer 130 may be disposed at an upper portion of the semiconductor device 10. The upper bonding dielectric layer 130 may surround the upper dummy pad 110 and the upper connection pad 120.

The upper dummy pad 110, the upper connection pad 120, and the upper bonding dielectric layer 130 may be components provided for hybrid bonding. The upper connection pad 120 may be a metal pad provided for electrical connection (e.g., transmission of a signal or power) with an external semiconductor device disposed on the semiconductor device 10. Unlike the upper connection pad 120, the upper dummy pad 110 may be a metal pad provided to improve bonding reliability and may not form an electrical connection path with the external semiconductor device.

The upper bonding dielectric layer 130 may surround sidewalls of the upper dummy pad 110 and the upper connection pad 120. The upper bonding dielectric layer 130 may not surround the top surface 110ts of the upper dummy pad 110 and a top surface of the upper connection pad 120. The top surface 110ts of the upper dummy pads 110, the top surface of the upper connection pads 120, and a top surface of the upper bonding dielectric layer 130 may be aligned at the same vertical level (or at the same height) and may form a continuous surface or may be coplanar. The top surface 110ts of the upper dummy pads 110, the top surface of the upper connection pads 120, and a top surface of the upper bonding dielectric layer 130 may be coplanar. Accordingly, the top surface 110ts of the upper dummy pad 110, the upper connection pad 120, and the upper bonding dielectric layer 130 may be exposed outward, as shown in FIG. 1.

According to an embodiment, the plurality of upper dummy pads 110 and the plurality of upper connection pads 120 may be alternately arranged with respect to each other along the horizontal direction. As shown in FIG. 1, the plurality of upper dummy pads 110 and the plurality of upper connection pads 120 may be alternately arranged along the first horizontal direction and the second horizontal direction. However, FIG. 1 illustrates an example in which the plurality of upper dummy pads 110 and the plurality of upper connection pads 120 are alternately arranged. The plurality of upper dummy pads 110 and the plurality of upper connection pads 120 may, of course, be disposed at the upper portion of the semiconductor device 10 based on various layout schemes or patterns.

A shape of the top surface of the upper dummy pad 110 may be the same as a shape of the top surface of the upper connection pad 120. In some embodiments, when a shape of the top surface of the upper connection pad 120 is rectangular, a shape of the top surface 110ts of the upper dummy pad 110 may also be rectangular. In some embodiments, when the top surface of the upper connection pad 120 has a circular shape, the top surface 110ts of the upper dummy pad 110 may also have a circular shape. Although FIG. 1 illustrates a shape of the top surface 110ts of the upper dummy pad 110 and a shape of the top surface of the upper connection pad 120 as rectangular, this is an example, and the top surface 110ts of the upper dummy pad 110 and the top surface of the upper connection pad 120 may, of course, be implemented in various shapes.

Referring to FIG. 2, the semiconductor device 10 may include a semiconductor structure 100, the upper dummy pad 110, the upper connection pad 120, the upper bonding dielectric layer 130, and an upper wiring structure 140.

The semiconductor structure 100 may include a semiconductor substrate and a semiconductor element layer. The semiconductor element layer may be disposed on the semiconductor substrate. The semiconductor structure 100 may be arranged such that the semiconductor element layer faces the upper wiring structure 140.

The semiconductor substrate of the semiconductor structure 100 may include silicon (Si), for example, crystalline silicon, polycrystalline silicon, or amorphous silicon. In another example, the semiconductor substrate may include a semiconductor element such as germanium (Ge), or a compound semiconductor such as silicon carbide (SiC), gallium arsenide (GaAs), indium arsenide (InAs), and indium phosphide (InP). For example, the semiconductor substrate may have a silicon on insulator (SOI) structure. For example, the semiconductor substrate may include a buried oxide (BOX) layer. The semiconductor substrate may include conductive regions, for example, impurity-doped wells or impurity-doped structures.

The semiconductor element layer of the semiconductor structure 100 may include a plurality of semiconductor elements and an interlayer dielectric layer covering the elements. The semiconductor elements may include active elements and passive elements. The active elements may include switching elements such as transistors, diodes, and memory cells. The passive elements may be elements that adjust electrical characteristics such as resistors, capacitors, inductors, and the like.

In some embodiments, when the semiconductor structure 100 is provided as a cell array structure, the semiconductor element layer of the semiconductor structure 100 may include a memory cell array. The memory cell array may include a plurality of memory cells. Each of the plurality of memory cells may include a selection element and a data storage element. The selection element and the data storage element may be electrically connected in series. The data storage element may be connected between a bit line and the selection element, and the selection element may be connected between the data storage element and a word line. The selection element may be a field effect transistor (FET), and the data storage element may be implemented as a capacitor or a variable resistor. For example, the selection element may include a transistor, a gate electrode of the transistor , and drain/source terminals of the transistor. The gate electrode of the transistor may be connected to the word line, and the drain/source terminals of the transistor may be connected to the bit line and the data storage element, respectively.

In some embodiments, when the semiconductor structure 100 is provided as a peripheral circuit structure, the semiconductor element layer of the semiconductor structure 100 may include circuit patterns including a core circuit and peripheral circuits. The core circuit and the peripheral circuits may include column decoders, sense amplifiers, control logic, and similar components.

The upper wiring structure 140 may be disposed on the semiconductor structure 100. According to some embodiments, the upper wiring structure 140 may be positioned on the semiconductor element layer of the semiconductor structure 100.

The upper wiring structure 140 may include an upper wiring pattern 141 and an upper wiring dielectric layer 142. The upper wiring pattern 141 may serve as an electrical connection path penetrating a top surface and a bottom surface of the upper wiring structure 140. The upper wiring dielectric layer 142 may include a plurality of dielectric material layers stacked in the vertical direction.

The upper wiring pattern 141 may include a metal or a metal alloy such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), but is not limited thereto. In some embodiments, the upper wiring pattern 141 may be formed by stacking a metal or a metal alloy on a seed layer including copper, titanium, titanium nitride, or titanium tungsten.

The upper wiring dielectric layer 142 may include silicon dioxide (SiO₂), aluminum oxide (Al₂O₃), hafnium oxide (HfO₂), zirconium oxide (ZrO₂), carbon-doped silicon oxide (SiOC), fluorine-doped silicon oxide (SiOF), or the like. The upper wiring dielectric layer 142 may include the plurality of dielectric material layers stacked in the vertical direction. A dielectric material layer positioned at an uppermost portion may be in contact with the upper bonding dielectric layer 130.

The upper wiring pattern 141 may include an upper wiring line pattern 141lp and an upper wiring via-pattern 141vp. The upper wiring line pattern 141lp may have a shape extending in the horizontal direction. The upper wiring via-pattern 141vp may have a shape that extends in the vertical direction by penetrating through the upper wiring dielectric layer 142. The upper wiring via-pattern 141vp may electrically connect the upper wiring line patterns 141lp positioned at different vertical levels. In some embodiments, at least some of the upper wiring line patterns 141lp may be integral with some of the upper wiring via-patterns 141vp.

In an embodiment, an upper seed layer may be positioned between the upper wiring pattern 141 and the upper wiring dielectric layer 142. In an embodiment, the upper seed layer may be formed by a physical vapor deposition (PVD) process, and the upper wiring pattern 141 may be formed by a plating process using the upper seed layer.

In an embodiment, the upper seed layer may include copper (Cu), titanium (Ti), titanium tungsten (TiW), titanium nitride (TiN), tantalum (Ta), tantalum nitride (TaN), chromium (Cr), aluminum (Al), or a combination thereof. For example, the upper seed layer may be Cu/Ti in which copper is stacked on titanium, or Cu/TiW in which copper is stacked on titanium tungsten. For example, when copper (Cu) is used as a material of the upper wiring pattern 141, at least a portion of the upper seed layer may function as a diffusion barrier layer.

The upper wiring pattern 141 may include an uppermost wiring pattern 141u. The uppermost wiring pattern 141u may be a wiring pattern positioned at a highest vertical level among the upper wiring patterns 141. As an example, the uppermost wiring pattern 141u may be a wiring pattern positioned at the highest vertical level among the upper wiring line patterns 141lp. The uppermost wiring pattern 141u may be surrounded by the upper wiring dielectric layer 142, and a bottom surface of the uppermost wiring pattern 141u may be in contact with the upper wiring via-pattern 141vp. As described above, the upper wiring dielectric layer 142 may include the plurality of dielectric material layers stacked in the vertical direction. In the disclosure, a dielectric material layer positioned at a vertical level higher than the uppermost wiring pattern 141u among the plurality of dielectric material layers may be referred to as an "uppermost wiring dielectric layer." For example, as shown in FIG. 2, a dielectric material layer positioned at a vertical level higher than an uppermost wiring vertical level uvl may be referred to as the uppermost wiring dielectric layer. The uppermost wiring vertical level uvl may refer to a vertical level at which the uppermost wiring pattern 141u is positioned. As an example, the uppermost wiring vertical level uvl may be a vertical level at which a top surface of the uppermost wiring pattern 141u is positioned.

The upper bonding dielectric layer 130 may be disposed on the upper wiring structure 140. For example, the upper bonding dielectric layer 130 may be positioned on an uppermost wiring dielectric layer of the upper wiring structure 140. According to some embodiments, the upper bonding dielectric layer 130 and the upper wiring dielectric layer 142 may include the same material. However, in some embodiments, the upper bonding dielectric layer 130 may include a different material from the upper wiring dielectric layer 142. The upper bonding dielectric layer 130 may include materials such as silicon dioxide (SiO₂), aluminum oxide (Al₂O₃), hafnium oxide (HfO₂), carbon-doped silicon oxide (SiOC), fluorine-doped silicon oxide (SiOF), zirconium oxide (ZrO₂), silicon nitride (Si₃N₄), hydrogen silsesquioxane (HSQ), spin-on glass (SOG), polyimide, benzocyclobutene (BCB), or the like.

The upper connection pad 120 may penetrate the upper bonding dielectric layer 130 in a downward direction (e.g., negative z-axis direction) from a top surface of the upper bonding dielectric layer 130. The upper dummy pad 110 may penetrate at least a portion of the upper bonding dielectric layer 130 in the downward direction from the top surface of the upper bonding dielectric layer 130. In some embodiments, as shown in FIG. 2, the upper dummy pad 110 may penetrate (e.g., completely penetrate) the upper bonding dielectric layer 130 in the downward direction (e.g., negative z-axis direction) from the top surface of the upper bonding dielectric layer 130. For example, a bottom surface 110bs of the upper dummy pad 110 may be in contact with the upper wiring dielectric layer 142 and may be surrounded by the upper wiring dielectric layer 142. In another embodiment, the upper dummy pad 110 may penetrate only a portion of the upper bonding dielectric layer 130 in the downward direction from a top surface of the upper bonding dielectric layer 130. For example, the bottom surface 110bs of the upper dummy pad 110 may be in contact with the upper bonding dielectric layer 130, may be surrounded by the upper bonding dielectric layer 130, and may be vertically spaced apart from the upper wiring dielectric layer 142.

The upper bonding dielectric layer 130 may be in contact with sidewalls of the upper connection pad 120 and the upper dummy pad 110, and may surround the sidewalls of the upper connection pad 120 and the upper dummy pad 110. According to some embodiments, each of the upper connection pad 120 and the upper dummy pad 110 may include a diffusion barrier layer. For example, the upper bonding dielectric layer 130 may be in contact with sidewalls of the diffusion barrier layer of the upper dummy pad 110 and sidewalls of the diffusion barrier layer of the upper connection pad 120, and may surround the sidewalls of the diffusion barrier layer of the upper dummy pad 110 and the sidewalls of the diffusion barrier layer of the upper connection pad 120.

The upper bonding dielectric layer 130 may expose a top surface 120ts of the upper connection pad 120 and the top surface 110ts of the upper dummy pad 110 upward. The upper bonding dielectric layer 130 may not surround the top surface 120ts of the upper connection pad 120 and the top surface 110ts of the upper dummy pad 110.

A bottom surface 120bs of the upper connection pad 120 may be in contact with the uppermost wiring pattern 141u. The bottom surface 120bs of the upper connection pad 120 may be positioned at the uppermost wiring vertical level uvl. According to some embodiments, the bottom surface 120bs of the upper connection pad 120 may include a flat surface. However, the bottom surface 120bs of the upper connection pad 120 may be implemented as a curved surface and is therefore not limited to a flat surface. A vertical level of the bottom surface 110bs of the upper dummy pad 110 may be higher than the uppermost wiring vertical level uvl and may also be higher than a vertical level of the bottom surface 120bs of the upper connection pad 120.

The bottom surface 110bs of the upper dummy pad 110 may include an embossed structure. In the disclosure, the embossed structure may mean a structure including a surface, the vertical level of which is not constant and has different vertical levels. As an example, the embossed structure may include a plurality of raised surfaces (or protruded surfaces) and may also include a plurality of recessed surfaces. The term "embossed structure" may be replaced with various terms such as "patterned surface structure," "uneven surface structure," "irregular surface structure," or "rough surface structure." However, in the disclosure, the term "embossed structure" is used as a unified expression.

According to some embodiments, a surface size (e.g., surface area) of the bottom surface 110bs of the upper dummy pad 110 may be larger than a surface size (e.g., surface area) of the bottom surface 120bsof the upper connection pad 120. For example, a surface size (e.g., surface area) of the top surface 110ts of the upper dummy pad 110 may be substantially equal to a surface size (e.g., surface area) of the top surface 120ts of the upper connection pad 120. By including the embossed structure, the bottom surface 110bs of the upper dummy pad 110 may have a larger surface size (e.g., larger surface area) than the bottom surface 120bs of the upper connection pad 120, which includes a flat structure.

The bottom surface 110bs of the upper dummy pad 110 may include a plurality of surfaces positioned at different vertical levels. In some embodiments, the bottom surface 110bs of the upper dummy pad 110 may include a lowest surface 110ls and a raised surface 110rs. The lowest surface 110ls may refer to a surface positioned at a lowest vertical level in the bottom surface 110bs of the upper dummy pad 110. In some embodiments, as shown in FIG. 2, the lowest surface 110ls may be a surface parallel to the horizontal direction. In some embodiments, the lowest surface 110ls may be implemented as a recessed surface in the downward direction (e.g., negative z-axis direction). The raised surface 110rs may be a surface that protrudes in an upward direction (e.g., positive z-axis direction) in the bottom surface 110bs of the upper dummy pad 110. The raised surface 110rs may be connected to the lowest surface 110ls and may be a surface protruding from the lowest surface 110ls in the upward direction.

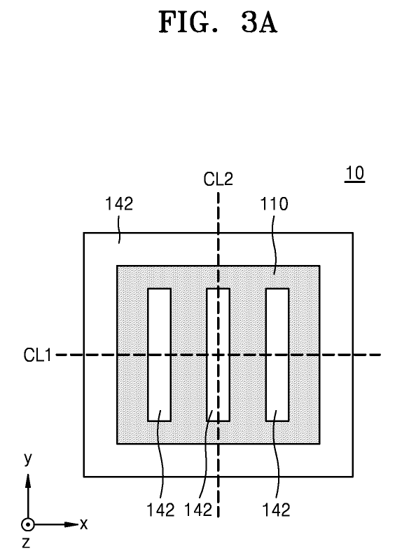

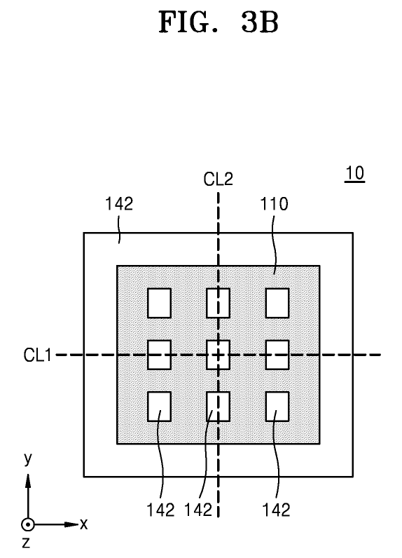

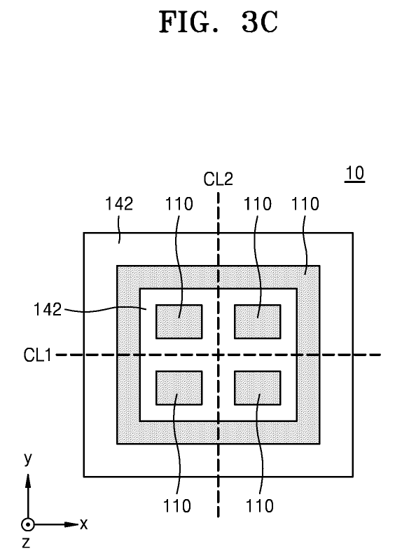

At a divided vertical level dvl that divides the raised surface 110rs of the upper dummy pad 110 into an upper portion and a lower portion, the upper dummy pad 110 and the upper wiring dielectric layer 142 may be alternately arranged along the horizontal direction. As an example, in a horizontal cross-section obtained by cutting the upper dummy pad 110 along a horizontal plane at the divided vertical level dvl, the upper dummy pad 110 and the upper wiring dielectric layer 142 may be alternately arranged along the first horizontal direction. The horizontal cross-section obtained by cutting the upper wiring dielectric layer 142 and the upper dummy pad 110 along the horizontal plane at the divided vertical level dvl will be described in detail in the following description of FIGS. 3A, 3B, and 3C.

According to some embodiments, the lowest surface 110ls may be in contact with the upper wiring dielectric layer 142 or may be surrounded by the upper wiring dielectric layer 142. The raised surface 110rs may also be in contact with the upper wiring dielectric layer 142 or may be surrounded by the upper wiring dielectric layer 142. In some embodiments, a portion of the raised surface 110rs (e.g., a lower portion of the raised surface 110rs) may be in contact with the upper wiring dielectric layer 142 or may be surrounded by the upper wiring dielectric layer 142, and a remaining portion of the raised surface 110rs (e.g., an upper portion of the raised surface 110rs) may be in contact with the upper bonding dielectric layer 130 or may be surrounded by the upper bonding dielectric layer 130.

According to some embodiments, the raised surface 110rs may include a convex surface 110cs and a sloped surface 110ss. The convex surface 110cs may be disposed at a central portion of the raised surface 110rs and may be a surface that is convex in the upward direction. In the vertical cross-section as in FIG. 2, the convex surface 110cs may have a symmetric structure with respect to a central axis CA. The central axis CA may be a vertical line passing through a center of the convex surface 110cs. For example, the center of the convex surface 110cs may be a highest point among a plurality of points included in the convex surface 110cs.

The sloped surface 110ss may refer to a surface positioned between the convex surface 110cs and the lowest surface 110ls. The sloped surface 110ss may be tilted with respect to the vertical direction. A slope direction of the sloped surface 110ss may be a direction in which a distance between the central axis CA and the sloped surface 110ss increases in the downward direction (e.g., negative z-axis direction). In some embodiments, the vertical cross-sectional view such as FIG. 2, an inclination angle of the sloped surface 110ss with respect to the vertical direction may be constant. For example, the sloped surface 110ss may be implemented as an inclined plane. In some embodiments, in the vertical cross-sectional view such as FIG. 2, an inclination angle of the sloped surface 110ss with respect to the vertical direction may increase in the downward direction. For example, the sloped surface 110ss may also be implemented as a curved surface.

In some embodiments, as shown in FIG. 2, the sloped surface 110ss may be in contact with the upper wiring dielectric layer 142 or may be surrounded by the upper wiring dielectric layer 142. The convex surface 110cs may be surrounded by the upper wiring dielectric layer 142. In another example, the convex surface 110cs may be surrounded by the upper bonding dielectric layer 130. When the convex surface 110cs is surrounded by the upper bonding dielectric layer 130, an entire portion of the convex surface 110cs may be surrounded by the upper bonding dielectric layer 130, or a portion of the convex surface 110cs (for example, a lower portion of the convex surface 110cs) may be surrounded by the upper wiring dielectric layer 142, and a remaining portion of the convex surface 110cs (for example, an upper portion of the convex surface 110cs) may be surrounded by the upper bonding dielectric layer 130.

In some embodiments, a portion of the sloped surface 110ss (e.g., a lower portion of the sloped surface 110ss) may be in contact with or surrounded by the upper wiring dielectric layer 142, and a remaining portion of the sloped surface 110ss (e.g., an upper portion of the sloped surface 110ss) may be in contact with or surrounded by the upper bonding dielectric layer 130. For example, the convex surface 110cs may be surrounded by the upper bonding dielectric layer 130.

FIG. 2 illustrates that the bottom surface 110bs of the upper dummy pad 110 may include three raised surfaces 110rs in the vertical cross-sectional view, and this is an example. The bottom surface 110bs of the upper dummy pad 110 may include various numbers of raised surfaces 110rs, such as fewer than three raised surfaces 110rs or four or more raised surfaces 110rs. FIG. 2 illustrates that the three raised surfaces 110rs have the same protrusion degree, but this is an example. The degree of upward protrusion of each of the plurality of raised surfaces 110rs included in the bottom surface 110bs of the upper dummy pad 110 may be the same or different.

As the number of raised surfaces 110rs included in the bottom surface 110bs of the upper dummy pad 110 increases and as the degree of upward protrusion of the raised surfaces 110rs increases, the amount of metal material forming the upper dummy pad 110 may decrease, and a vertical distance between the bottom surface 110bs of the upper dummy pad 110 and the uppermost wiring pattern 141u may increase. The semiconductor device 10 according to an embodiment, may include the upper dummy pad 110 that includes the raised surfaces 110rs having an appropriate protrusion degree and/or an appropriate number of the raised surfaces 110rs, so that an unnecessary electrical connection (e.g., contact with the uppermost wiring pattern 141u) may be prevented and bonding reliability may be improved. For example, the shape of the top surface 110ts of the upper dummy pad 110 is the same as that of the top surface 120ts of the upper connection pad 120, such that, when viewed from above (or in plan view), a plurality of metal pads may be uniformly distributed over a top surface of the semiconductor device 10. Accordingly, the bonding reliability of the semiconductor device 10 may be improved in hybrid bonding.

FIGS. 3A, 3B, and 3C are cross-sectional views of the semiconductor device 10 according to an embodiment.

Each of FIGS. 3A, 3B, and 3C is a horizontal cross-sectional view taken at a horizontal plane at the divided vertical level dvl of the upper dummy pad 110 and the upper wiring dielectric layer 142 of FIG. 2. Referring to the horizontal cross-sectional views of FIGS. 3A, 3B, and 3C, the upper dummy pad 110 and the upper wiring dielectric layer 142 may be alternately arranged along the horizontal direction. FIGS. 3A, 3B, and 3C each illustrate the upper dummy pad 110 according to different embodiments.

As in the horizontal cross-sectional view of FIG. 3A, the upper dummy pad 110, the upper wiring dielectric layer 142, the upper dummy pad 110, the upper wiring dielectric layer 142, the upper dummy pad 110, the upper wiring dielectric layer 142, and the upper dummy pad 110 may be sequentially arranged along the first horizontal direction. As another example, in the horizontal cross-sectional view, along the second horizontal direction, the upper dummy pad 110, the upper wiring dielectric layer 142, and the upper dummy pad 110 may be arranged in this order.

In the horizontal cross-sectional view of FIG. 3A, the upper dummy pad 110 may surround the upper wiring dielectric layer 142. In the horizontal cross-sectional view, the upper wiring dielectric layer 142 may be surrounded by the upper dummy pad 110 and may appear as three bar shapes extended in the second horizontal direction.

In the horizontal cross-sectional view of FIG. 3A, each of the upper dummy pad 110 and the upper wiring dielectric layer 142 may be arranged mirror-symmetrically with respect to a centerline (e.g., a first centerline CL1 or a second centerline CL2). The centerline may refer to a horizontal line that bisects (or intersects) the upper dummy pad 110. For example, the first centerline CL1 may be a line in the first horizontal direction (e.g., the x-axis direction) bisecting (or intersecting) the upper dummy pad 110 in the horizontal cross-sectional view, and the second centerline CL2 may be a line in a second horizontal direction (e.g., the y-axis direction) bisecting (or intersecting) the upper dummy pad 110 in the horizontal cross-sectional view.

In the horizontal cross-sectional view of FIG. 3B, the upper dummy pad 110 may surround the upper wiring dielectric layer 142, and the upper wiring dielectric layer 142 may be arranged in the form of independent islands surrounded by the upper dummy pad 110. For example, in the horizontal cross-sectional view, the upper wiring dielectric layer 142 may be arranged in the form of nine islands surrounded by the upper dummy pad 110. In the horizontal cross-sectional view, the upper wiring dielectric layer 142 may be spaced apart and arranged at regular intervals (or distances) in the first horizontal direction and the second horizontal direction.

For example, in the horizontal cross-sectional view of FIG. 3B, along the first horizontal direction, the upper dummy pad 110, the upper wiring dielectric layer 142, the upper dummy pad 110, the upper wiring dielectric layer 142, the upper dummy pad 110, the upper wiring dielectric layer 142, and the upper dummy pad 110 may be sequentially arranged. In the horizontal cross-sectional view, along the second horizontal direction as well, the upper dummy pad 110, the upper wiring dielectric layer 142, the upper dummy pad 110, the upper wiring dielectric layer 142, the upper dummy pad 110, the upper wiring dielectric layer 142, and the upper dummy pad 110 may be sequentially arranged. In the horizontal cross-sectional view, the upper dummy pad 110 and the upper wiring dielectric layer 142 may be arranged mirror-symmetrically with respect to the centerline (e.g., the first centerline CL1 or the second centerline CL2).

In the horizontal cross-sectional view of FIG. 3C, the upper wiring dielectric layer 142 may surround the upper dummy pad 110, and the upper dummy pad 110 may be arranged in the form of independent islands surrounded by the upper wiring dielectric layer 142. For example, in the horizontal cross-sectional view, the upper dummy pads 110 may be arranged in the form of four islands surrounded by the upper wiring dielectric layer 142. In the horizontal cross-sectional view, the upper dummy pads 110 may be spaced apart at regular intervals (or distances) in the first horizontal direction (e.g., the x-axis direction) and the second horizontal direction (e.g., the y-axis direction).

For example, in the horizontal cross-sectional view of FIG. 3C, the upper dummy pad 110, the upper wiring dielectric layer 142, the upper dummy pad 110, the upper wiring dielectric layer 142, the upper dummy pad 110, the upper wiring dielectric layer 142, and the upper dummy pad 110 may be sequentially arranged along the first horizontal direction (e.g., the x-axis direction). In the horizontal cross-sectional view, the upper dummy pad 110, the upper wiring dielectric layer 142, the upper dummy pad 110, the upper wiring dielectric layer 142, the upper dummy pad 110, the upper wiring dielectric layer 142, and the upper dummy pad 110 may also be sequentially arranged along the second horizontal direction (e.g., the y-axis direction). . In the horizontal cross-sectional view, the upper dummy pad 110 and the upper wiring dielectric layer 142 may be arranged mirror-symmetrically with respect to the centerline (e.g., the first centerline CL1 or the second centerline CL2).

Each of FIGS. 3A, 3B, and 3C is an example of a horizontal cross-sectional view obtained by cutting the upper dummy pad 110 along a horizontal plane at the divided vertical level dvl of FIG. 2, and the upper dummy pad 110 and the upper wiring dielectric layer 142 in the horizontal cross-sectional view indeed may be arranged in more diverse alternating layout structures.

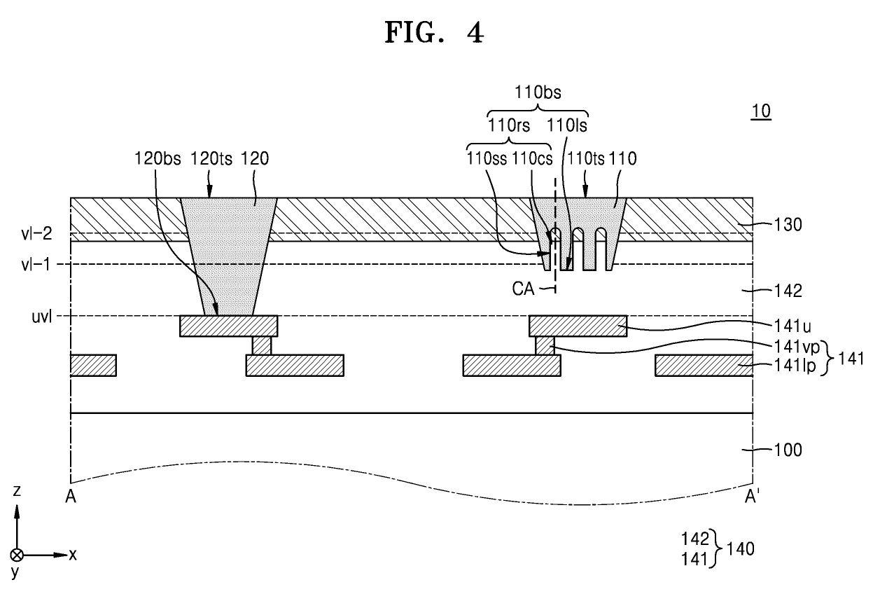

FIG. 4 is a cross-sectional view of the semiconductor device 10 according to an embodiment. FIG. 4 is a vertical cross-sectional view obtained by vertically cutting the semiconductor device 10 of FIG. 1 along the horizontal line (e.g., the first horizontal line A–A’). In the description of FIG. 4, redundant descriptions with respect to FIGS. 1 and 2 will be omitted, and differences from FIGS. 1 and 2 will be described in detail.

Referring to FIG. 4, the raised surface 110rs of the upper dummy pad 110 may protrude from the lowest surface 110ls to a vertical level higher than a bottom surface of the upper bonding dielectric layer 130. For example, a portion of the raised surface 110rs (e.g., an upper portion) may be surrounded by the upper bonding dielectric layer 130, and a remaining portion of the raised surface 110rs (e.g., a lower portion) may be surrounded by the upper wiring dielectric layer 142.

In some embodiments, the sloped surface 110ss may be surrounded by the upper wiring dielectric layer 142, and the convex surface 110cs may be surrounded by the upper bonding dielectric layer 130. In some embodiments, the sloped surface 110ss may be surrounded by the upper wiring dielectric layer 142, a portion (e.g., a lower portion) of the convex surface 110cs may be surrounded by the upper wiring dielectric layer 142, and only a remaining portion (e.g., an upper portion) of the convex surface 110cs may be surrounded by the upper bonding dielectric layer 130.

as shown in FIG. 4, at a first vertical level vl-1, the upper dummy pad 110 and the upper wiring dielectric layer 142 may be alternately arranged along the horizontal direction, and at a second vertical level vl-2, the upper dummy pad 110 and the upper bonding dielectric layer 130 may be alternately arranged along the horizontal direction. For example, in a horizontal cross-sectional view obtained by cutting the upper dummy pad 110 along a horizontal plane (parallel to the x-y plane) at the first vertical level vl-1, the upper dummy pad 110 and the upper wiring dielectric layer 142 may be alternately arranged along the first horizontal direction. In a horizontal cross-sectional view obtained by cutting the upper dummy pad 110 along a horizontal plane at the second vertical level vl-2, the upper dummy pad 110 and the upper bonding dielectric layer 130 may be alternately arranged along the first horizontal direction. The first vertical level vl-1 may be lower in vertical level than the second vertical level vl-2. For example, the first vertical level vl-1 may be closer to the semiconductor structure 100 than the second vertical level vl-2.

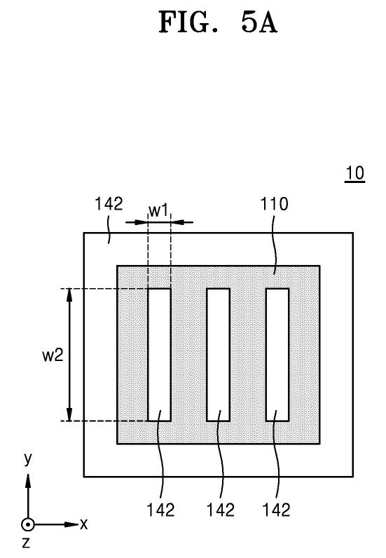

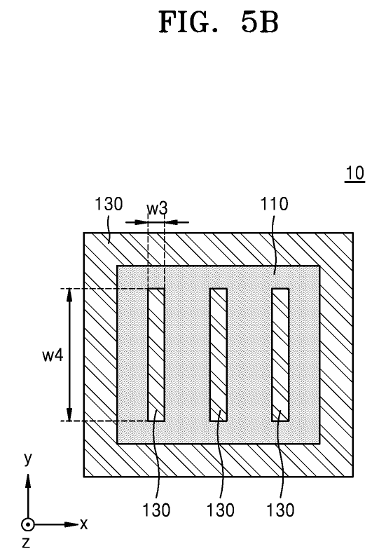

The horizontal cross-sectional views obtained by cutting the upper dummy pad 110 along the horizontal planes at the first vertical level vl-1 and the second vertical level vl-2 will be described in detail in the following descriptions of FIGS. 5A and 5B.

A volume of the upper dummy pad 110 of FIG. 4 may be smaller than a volume of the upper dummy pad 110 of FIG. 2. A mass of metal material forming the upper dummy pad 110 of FIG. 4 may be smaller than a mass of metal material forming the upper dummy pad 110 of FIG. 2. For example, as the degree of upward protrusion of the raised surface 110rs included in the upper dummy pad 110 increases, a mass of metal material included in the upper dummy pad 110 may decrease. According to an embodiment, by controlling the protrusion degree of the raised surface 110rs, a total amount of metal material disposed in an upper bonding region of the semiconductor device 10 may be controlled. As the total amount of metal material disposed in the upper bonding region is controlled, a warpage phenomenon, which is caused by an increase in the number of semiconductor layer stacks, may be prevented.

FIGS. 5A and 5B are cross-sectional views of the semiconductor device 10 according to an embodiment.

FIG. 5A is a horizontal cross-sectional view obtained by cutting the upper dummy pad 110 of FIG. 4 at the horizontal plane of the first vertical level vl-1, and FIG. 5B is a horizontal cross-sectional view obtained by cutting the upper dummy pad 110 of FIG. 4 at the horizontal plane of the second vertical level vl-2.

Referring to the horizontal cross-sectional view of FIG. 5A, the upper dummy pad 110 and the upper wiring dielectric layer 142 may be alternately arranged along the horizontal direction.

In the horizontal cross-sectional view of FIG. 5A, the upper dummy pad 110 may surround the upper wiring dielectric layer 142. In the horizontal cross-sectional view, the upper wiring dielectric layer 142 may be surrounded by the upper dummy pad 110 and may appear as three bar shapes elongated in the second horizontal direction. For example, the upper wiring dielectric layer 142 of the bar shape may have a first horizontal width w1 in the first horizontal direction (e.g., x-axis direction) and may have a second horizontal width w2 in the second horizontal direction (e.g., y-axis direction).

Referring to the horizontal cross-sectional view of FIG. 5B, the upper dummy pad 110 and the upper bonding dielectric layer 130 may be alternately arranged along the horizontal direction.

In the horizontal cross-sectional view of FIG. 5B, the upper dummy pad 110 may surround the upper bonding dielectric layer 130. In the horizontal cross-sectional view, the upper bonding dielectric layer 130 may be surrounded by the upper dummy pad 110 and may appear in three bar shapes elongated in a second horizontal direction (e.g., y-axis direction). For example, the upper bonding dielectric layer 130 of the bar shape may have a third horizontal width w3 in the first horizontal direction (e.g., x-axis direction) and a fourth horizontal width w4 in the second horizontal direction (e.g., y-axis direction). The first horizontal width w1 may be greater than the third horizontal width w3, and the second horizontal width w2 may be greater than the fourth horizontal width w4. In some embodiments, a ratio of the third horizontal width w3 to the first horizontal width w1 may be the same as a ratio of the fourth horizontal width w4 to the second horizontal width w2, such that w1/w3 = w2/w4.

FIGS. 5A and 5B illustrate that each of the upper wiring dielectric layer 142 and the upper bonding dielectric layer 130 is arranged in the bar shape extending in a second horizontal direction in the horizontal cross-sectional view, and this is an example. Each of the upper wiring dielectric layer 142 and the upper bonding dielectric layer 130 may be arranged, in the horizontal cross-sectional views, in various shapes or structures, such as independent island shapes surrounded by the upper dummy pad 110.

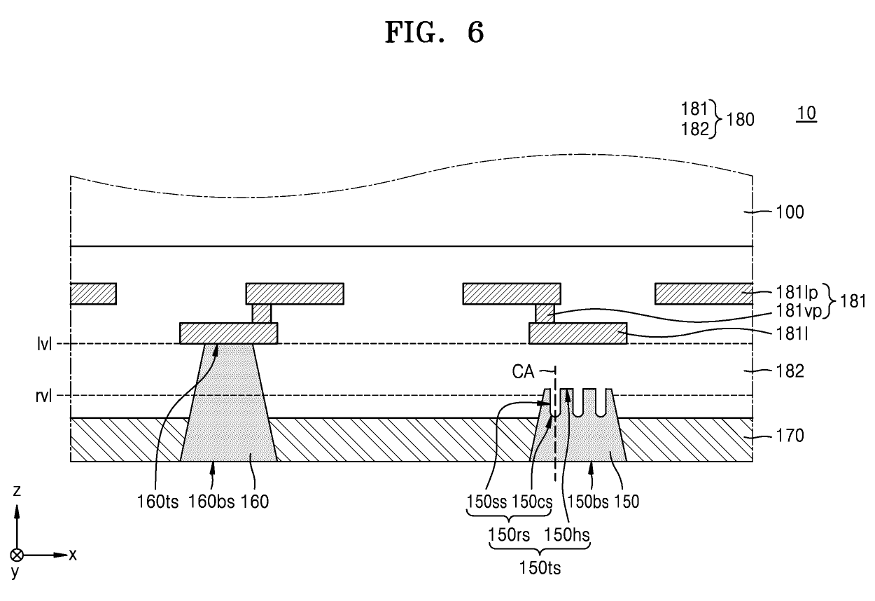

FIG. 6 is a cross-sectional view of the semiconductor device 10 according to an embodiment. FIG. 6 illustrates a lower structure of the semiconductor device 10.

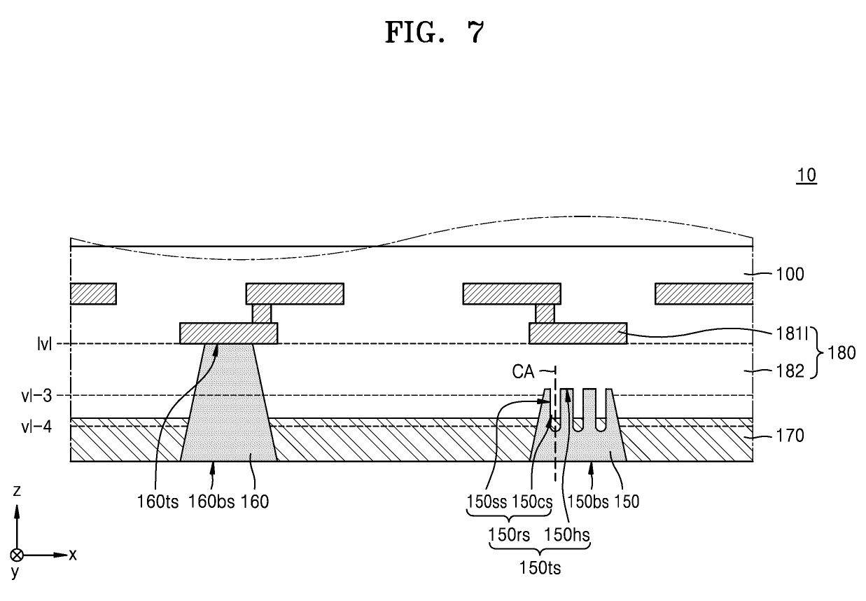

As described above with reference to FIGS. 1, 2, 3A, 3B, 3C, and 4, 5A, and 5B, the semiconductor device 10 according to an embodiment may include an upper bonding structure that is configured with the upper dummy pad 110, the upper connection pad 120, and the upper bonding dielectric layer 130, which are disposed in the upper portion of the semiconductor device 10. The semiconductor device 10 according to an embodiment may include a lower bonding structure that is configured with a lower dummy pad 150, a lower connection pad 160, and a lower bonding dielectric layer 170, which are disposed in a lower portion of the semiconductor device 10. In some embodiments, the semiconductor device 10 may include only the upper bonding structure and may not include the lower bonding structure. In some embodiments, the semiconductor device 10 may include only the lower bonding structure and may not include the upper bonding structure. In some embodiments, the semiconductor device 10 may include both the upper bonding structure and the lower bonding structure. In the descriptions of FIGS. 6 and 7, the lower bonding structure of the semiconductor device 10 will be described in detail.

Referring to FIG. 6, the semiconductor device 10 may include the lower dummy pad 150, the lower connection pad 160, the lower bonding dielectric layer 170, and a lower wiring structure 180.

Each of the structures of the lower dummy pad 150, the lower connection pad 160, and the lower bonding dielectric layer 170 may have a vertical symmetrical relationship with the structures of the upper dummy pad 110, the upper connection pad 120, and the upper bonding dielectric layer 130, respectively, as described with reference to FIG. 2. Therefore, redundant descriptions between the lower dummy pad 150, the lower connection pad 160, and the lower bonding dielectric layer 170 and the corresponding upper components (the upper dummy pad 110, the upper connection pad 120, and the upper bonding dielectric layer 130) will be omitted.

The lower wiring structure 180 may be disposed under the semiconductor structure 100. In some embodiments, the lower wiring structure 180 may be positioned under the semiconductor substrate of the semiconductor structure 100.

The lower wiring structure 180 may include a lower wiring pattern 181 and a lower wiring dielectric layer 182. The lower wiring pattern 181 may serve or function as an electrical connection path that penetrates upper and bottom surfaces of the lower wiring structure 180. The lower wiring dielectric layer 182 may include a plurality of dielectric material layers stacked vertically, and a dielectric material layer positioned at the lowest portion among the plurality of dielectric material layers may be in contact with the lower bonding dielectric layer 170. In the disclosure, a dielectric material layer disposed at a vertical level lower than a lowermost wiring pattern 181l among the plurality of dielectric material layers may be referred to as a "lowermost wiring dielectric layer." For example, as shown in FIG. 6, a dielectric material layer disposed at a vertical level lower than the lowermost wiring vertical level lvl may be referred to as a lowermost wiring dielectric layer. The lowermost wiring vertical level lvl may refer to a vertical level at which the lowermost wiring pattern 181l is disposed. For example, the lowermost wiring vertical level lvl may be a vertical level at which a bottom surface of the lowermost wiring pattern 181l is positioned.

The lower wiring pattern 181 may include a lower wiring line pattern 181lp and a lower wiring via-pattern 181vp. The lower wiring pattern 181 may include the lowermost wiring pattern 181l. A lowermost wiring pattern 181u may be a wiring pattern that is disposed at a lowest vertical level among the lower wiring patterns 181.

The lower bonding dielectric layer 170 may be disposed under the lower wiring structure 180. For example, the lower bonding dielectric layer 170 may be positioned under the lowermost wiring dielectric layer.

A lower connection pad 160 may penetrate the lower bonding dielectric layer 170 in the upward direction (e.g., positive z-axis direction) from a bottom surface of the lower bonding dielectric layer 170. The lower dummy pad 150 may penetrate at least a portion of the lower bonding dielectric layer 170 from the bottom surface of the lower bonding dielectric layer 170 in the upward direction. In some embodiments, as shown in FIG. 6, the lower dummy pad 150 may penetrate (e.g., completely penetrate) the lower bonding dielectric layer 170 from the bottom surface of the lower bonding dielectric layer 170 in the upward direction. For example, a top surface 150ts of the lower dummy pad 150 may be in contact with the lower wiring dielectric layer 182 and may be surrounded by the lower wiring dielectric layer 182. In some other embodiment, the lower dummy pad 150 may penetrate only a portion of the lower bonding dielectric layer 170 from the bottom surface of the lower bonding dielectric layer 170 in the upward direction. For example, the top surface 150ts of the lower dummy pad 150 may be in contact with and surrounded by the lower bonding dielectric layer 170, and may be vertically spaced apart from the lower wiring dielectric layer 182.

The lower bonding dielectric layer 170 may expose downward a bottom surface 160bs of the lower connection pad 160 and a bottom surface 150bs of the lower dummy pad 150. The lower bonding dielectric layer 170 may not surround the bottom surface 160bs of the lower connection pad 160 and the bottom surface 150bs of the lower dummy pad 150. The bottom surface of the lower bonding dielectric layer 170, the bottom surface 160bs of the lower connection pad 160, and the bottom surface 150bs of the lower dummy pad 150 may form a continuous surface or may be coplanar.

A top surface 160ts of the lower connection pad 160 may be in contact with the lowermost wiring pattern 181l. A vertical level of the top surface 160ts of the lower connection pad 160 may be the same as the lowermost wiring vertical level lvl. A vertical level of the top surface 150ts of the lower dummy pad 150 may be lower than the lowermost wiring vertical level lvl and may also be lower than a vertical level of the top surface 160ts of the lower connection pad 160.

The top surface 150ts of the lower dummy pad 150 may include an embossed structure. In some embodiments, a surface size (e.g., surface area) of the top surface 150ts of the lower dummy pad 150 may be greater than a surface size (e.g., surface area) of the top surface 160ts of the lower connection pad 160. For example, the surface size (e.g., surface area) of the bottom surface 150bs of the lower dummy pad 150 may be substantially equal to the surface size (e.g., surface area) of the bottom surface 160bs of the lower connection pad 160.

The top surface 150ts of the lower dummy pad 150 may include a plurality of surfaces disposed at different vertical levels. In some embodiments, the top surface 150ts of the lower dummy pad 150 may include a highest surface 150hs and a recessed surface 150rs. The highest surface 150hs may refer to a surface among the top surfaces 150ts of the lower dummy pad 150 that is disposed at the highest vertical level. The recessed surface 150rs may be a surface of the top surface 150ts of the lower dummy pad 150 that is recessed in the downward direction (e.g., negative z-axis direction). The recessed surface 150rs may be connected to the highest surface 150hs and may be a surface recessed downward from the highest surface 150hs.

At a dummy vertical level rvl that divides the recessed surface 150rs of the lower dummy pad 150 into an upper portion and a lower portion, the lower dummy pad 150 and the lower wiring dielectric layer 182 may be alternately arranged along the horizontal direction. For example, in a horizontal cross-sectional view obtained by cutting the lower dummy pad 150 along a horizontal plane (parallel to an xy plane) at the dummy vertical level rvl, the lower dummy pad 150 and the lower wiring dielectric layer 182 may be alternately arranged along the first horizontal direction. For example, the horizontal cross-sectional view obtained by cutting the lower dummy pad 150 at the horizontal plane at the dummy vertical level rvl may have the same shape as that shown in FIGS. 3A, 3B, and 3C. The horizontal cross-sectional view may not be limited to the cross-sectional views illustrated in FIGS. 3A, 3B, and 3C and may appear in various arrangement structures of the lower dummy pad 150 and the lower wiring dielectric layer 182 alternately arranged along a horizontal direction.

In some embodiments, the recessed surface 150rs may include a concave surface 150cs and a sloped surface 150ss. The concave surface 150cs may be disposed at a central portion of the recessed surface 150rs and may be a surface concave in the downward direction. In the vertical cross-sectional view such as FIG. 6, the concave surface 150cs may have a symmetrical structure with respect to the central axis CA. The central axis CA may be a vertical line passing through a center of the concave surface 150cs. For example, the center of the concave surface 150cs may be the lowest point among a plurality of points included in the concave surface 150cs.

The sloped surface 150ss may refer to a surface positioned between the concave surface 150cs and the highest surface 150hs. The sloped surface 150ss may be inclined with respect to the vertical direction. An inclination direction of the sloped surface 150ss may be a direction in which a distance between the central axis CA and the sloped surface 150ss increases in the upward direction (e.g., positive z-axis direction).

FIG. 6 illustrates that the top surface 150ts of the lower dummy pad 150 may include three recessed surfaces 150rs in the vertical cross-sectional view, and this is an example. The top surface 150ts of the lower dummy pad 150 may include fewer than three recessed surfaces 150rs or four or more recessed surfaces 150rs, not being limited thereto. For example, the top surface 150ts may include various numbers of recessed surfaces 150rs. FIG. 6 illustrates that the three recessed surfaces 150rs have the same degree of recess (or recess depth), but this is an example. The degree of recess in the downward direction of the plurality of recessed surfaces 150rs included in the top surface 150ts of the lower dummy pad 150 may be the same, or may be different from each other.

FIG. 7 is a cross-sectional view of the semiconductor device 10 according to an embodiment. In the description of FIG. 7, redundant descriptions with respect to FIG. 6 will be omitted, and differences from the semiconductor device 10 of FIG. 6 will be described in detail.

Referring to FIG. 7, the degree of recess of the recessed surface 150rs of the lower dummy pad 150 in FIG. 7 may be greater than the degree of recess of the recessed surface 150rs of the lower dummy pad 150 in FIG. 6.

As shown in FIG. 7, a portion of the recessed surface 150rs of the lower dummy pad 150 (e.g., an upper portion of the recessed surface 150rs may be surrounded by the lower wiring dielectric layer 182, and a remaining portion (e.g., a lower portion of the recessed surface 150rs) may be surrounded by the lower bonding dielectric layer 170.

In some embodiments, in a horizontal cross-sectional view obtained by cutting the lower dummy pad 150 along a horizontal plane at a third vertical level vl-3, the lower dummy pad 150 and the lower wiring dielectric layer 182 may be alternately arranged along the horizontal direction. For example, in a horizontal cross-sectional view obtained by cutting the lower dummy pad 150 along a horizontal plane at a fourth vertical level vl-4, the lower dummy pad 150 and the lower bonding dielectric layer 170 may be alternately arranged along the horizontal direction. The third vertical level vl-3 may be higher than the fourth vertical level vl-4. For example, the third vertical level vl-3 may be closer to the semiconductor structure 100 than the fourth vertical level vl-4.

For example, the horizontal cross-sectional view obtained by cutting the lower dummy pad 150 along the horizontal plane at the third vertical level vl-3 may have the same shape as the horizontal cross-sectional view of FIG. 5A, and the horizontal cross-sectional view obtained by cutting the lower dummy pad 150 at the fourth vertical level vl-4 may have the same shape as the horizontal cross-sectional view of FIG. 5B. However, the horizontal cross-sectional view obtained by cutting the lower dummy pad 150 along the horizontal plane at the third vertical level vl-3 is not limited to the horizontal cross-sectional view of FIG. 5A, and may appear in various arrangement structures in which the lower dummy pad 150 and the lower wiring dielectric layer 182 are alternately arranged along the horizontal direction. For example, the horizontal cross-sectional view obtained by cutting the lower dummy pad 150 along the horizontal plane at the fourth vertical level vl-4 is also not limited to the horizontal cross-sectional view of FIG. 5B, and may appear in various arrangement structures in which the lower dummy pad 150 and the lower bonding dielectric layer 170 are alternately arranged along the horizontal direction.

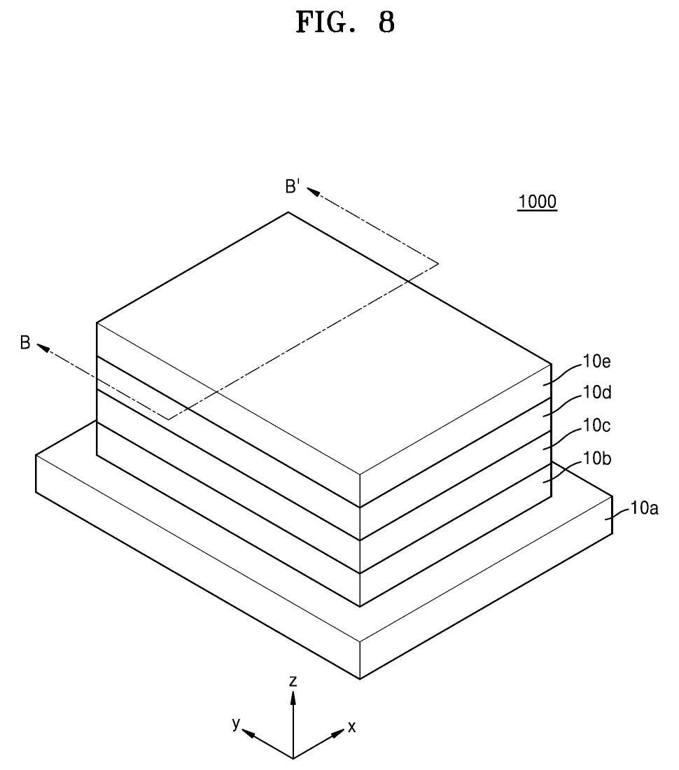

Descriptions of FIGS. 8 to 10 will briefly explain semiconductor devices according to various embodiments including a hybrid bonding structure.

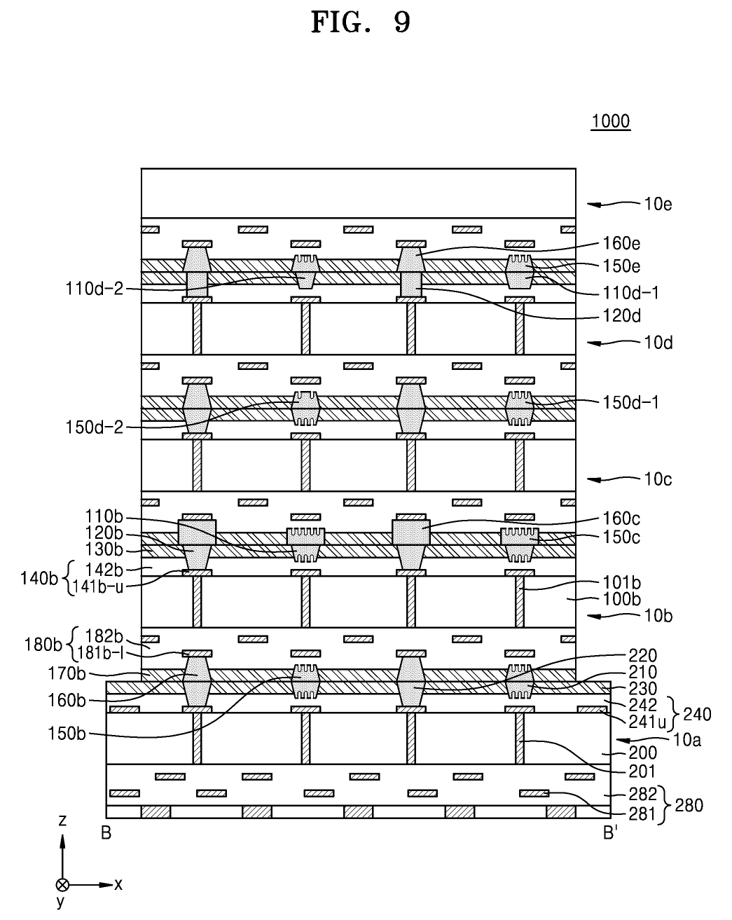

FIG. 8 is a perspective view of a semiconductor device 1000 according to an embodiment. FIG. 9 is a cross-sectional view of the semiconductor device 1000 according to an embodiment. FIG. 9 is a vertical cross-sectional view obtained by vertically cutting the semiconductor device 1000 of FIG. 8 along a horizontal line B–B′.

According to an embodiment, the semiconductor device 1000 may include a plurality of stacked structures (e.g., first to fifth stacked structures 10a through 10e) stacked in the vertical direction. Each of the plurality of stacked structures included in the semiconductor device 1000 may be a semiconductor device including a semiconductor structure, a wiring structure, and a bonding structure. For example, the first stacked structure 10a may include the semiconductor device 10 including the upper bonding structure described in FIGS. 1, 2, 3A, 3B, 3C, 4, 5A, and 5B. As another example, the fifth stacked structure 10e may include the semiconductor device 10 including the lower bonding structure described in FIGS. 6 and 7. As another example, each of the second to fourth stacked structures 10b, 10c, and 10d may include the semiconductor device 10 including both the upper bonding structure described in FIGS. 1, 2, 3A, 3B, 3C, 4, 5A, and 5B and the lower bonding structure described in FIGS. 6 and 7.

The first stacked structure 10a may include a stacked structure positioned at a lowest level among the plurality of stacked structures. The first stacked structure 10a may include a first semiconductor structure 200, a first upper wiring structure 240, a first upper bonding dielectric layer 230, a first upper dummy pad 210, a first upper connection pad 220, and a first lower wiring structure 280. The first lower wiring structure 280 may include a first lower wiring pattern 281 and a first lower wiring dielectric layer 282, and the first upper wiring structure 240 may include a first uppermost wiring pattern 241u and a first upper wiring dielectric layer 242. The first upper dummy pad 210 may not be in contact with the first uppermost wiring pattern 241u and may be vertically spaced apart from the first uppermost wiring pattern 241u. For example, a bottom surface of the first upper connection pad 220 may be in contact with the first uppermost wiring pattern 241u. For example, the first stacked structure 10a may include a first through-electrode 201. The first through-electrodes 201 may electrically connect the first upper wiring structure 240 and the first lower wiring structure 280 respectively, and may vertically penetrate a top surface and a bottom surface of the first semiconductor structure 200.

The second stacked structure 10b may be a stacked structure disposed on the first stacked structure 10a and disposed under a third stacked structure 10c. The second stacked structure 10b may include a second semiconductor structure 100b, a second upper wiring structure 140b, a second upper bonding dielectric layer 130b, a second upper dummy pad 110b, a second upper connection pad 120b, a second lower wiring structure 180b, a second lower bonding dielectric layer 170b, a second lower connection pad 160b, and a second lower dummy pad 150b.

The second upper wiring structure 140b may include a second uppermost wiring pattern 141b-u and a second upper wiring dielectric layer 142b. A bottom surface of the second upper connection pad 120b may be in contact with the second uppermost wiring pattern 141b-u, while a bottom surface of the second upper dummy pad 110b may be vertically spaced apart from the second uppermost wiring pattern 141b-u without making contact.

The second lower wiring structure 180b may include a second lowermost wiring pattern 181b-l and a second lower wiring dielectric layer 182b. A top surface of the second lower connection pad 160b may be in contact with the second lowermost wiring pattern 181b-1, while a top surface of the second lower dummy pad 150b may be vertically spaced apart from the second lowermost wiring pattern 181b-1 without making contact.

The second stacked structure 10b may further include a second through-electrode 101b. The second through-electrode 101b may electrically connect the second upper wiring structure 140b and the second lower wiring structure 180b, and may vertically penetrate a top surface and a bottom surface of the second semiconductor structure 100b.

In another example, the second uppermost wiring pattern 141b-u may include the second through-electrode 101b. For example, the wiring pattern surrounded by the second upper wiring dielectric layer 142b may solely be the second through-electrode 101b. For example, the bottom surface of the second upper connection pad 120b may be in contact with (e.g., in direct contact with) the second through-electrode 101b, while the bottom surface of the second upper dummy pad 110b, without contacting the second through-electrode 101b, may be vertically spaced apart from a top surface of the second through-electrode 101b.

The second lower bonding dielectric layer 170b may be disposed on the first upper bonding dielectric layer 230. The second lower dummy pad 150b may be disposed on the first upper dummy pad 210. In some embodiments, the second lower dummy pad 150b may be arranged in alignment with the first upper dummy pad 210. In some embodiments, the second lower dummy pad 150b may not be exactly aligned with the first upper dummy pad 210 and may be disposed on the first upper dummy pad 210 in a slightly misaligned state.

The second lower connection pad 160b may be disposed on the first upper connection pad 220. In some embodiments, the second lower connection pad 160b may be arranged in alignment with the first upper connection pad 220. In some embodiments, the second lower connection pad 160b may not be exactly aligned with the first upper connection pad 220 and may be disposed on the first upper connection pad 220 in a slightly misaligned state.

As described above, because the second lower dummy pad 150b is disposed on the first upper dummy pad 210, the second lower connection pad 160b is disposed on the first upper connection pad 220, and the second lower bonding dielectric layer 170b is disposed on the first upper bonding dielectric layer 230, and accordingly, the first stacked structure 10a and the second stacked structure 10b may form a hybrid bonding structure. A hybrid bonding structure formed by the second stacked structure 10b and the third stacked structure 10c, a hybrid bonding structure formed by the third stacked structure 10c and the fourth stacked structure 10d, and a hybrid bonding structure formed by the fourth stacked structure 10d and the fifth stacked structure 10e may also be formed based on the same principle.

In some embodiments, an upper dummy pad of a lower stacked structure and a lower dummy pad of an upper stacked structure may include different structures. As a specific example, fourth upper dummy pads 110d-1 and 110d-2 of the fourth stacked structure 10d may not include an embossed surface structure, while the fifth lower dummy pad 150e of a fifth stacked structure 10e may include the embossed surface structure. As another example, the second upper dummy pad 110b of the second stacked structure 10b may have a trapezoidal shape in a vertical cross-sectional view, while a third lower dummy pad 150c of the third stacked structure 10c may have a rectangular shape in the vertical cross-sectional view.

In some embodiments, an upper connection pad of the lower stacked structure and a lower connection pad of an upper stacked structure may include different structures. As a specific example, a fourth upper connection pad 120d of a fourth stacked structure 10d may have a rectangular shape in the vertical cross-sectional view, while a fifth lower connection pad 160e of a fifth stacked structure 10e may have the trapezoidal shape in the vertical cross-sectional view. As another example, the second upper connection pad 120b of the second stacked structure 10b may have the trapezoidal shape in the vertical cross-sectional view, while a third lower connection pad 160c of a third stacked structure 10c may have the rectangular shape in the vertical cross-sectional view.

In some embodiments, structures of dummy pads included in a single stacked structure may be different from each other. As a specific example, one dummy pad 110d-1 among the fourth upper dummy pads 110d-1 and 110d-2 of the fourth stacked structure 10d may have a greater horizontal width than the other dummy pad 110d-2. As another example, among fourth lower dummy pads 150d-1 and 150d-2 of the fourth stacked structure 10d, one dummy pad 150d-1 may include two recessed surfaces in the vertical cross-sectional view, while the other dummy pad 150d-2 may include three recessed surfaces.

As described above, dummy pads and connection pads included in each of the plurality of stacked structures may be implemented in various shapes, and dummy pads and connection pads included in two stacked structures (e.g., the second stacked structure 10b and the third stacked structure 10c) arranged adjacent to each other may be arranged in vertically symmetric structures or may be arranged in vertically asymmetric structures.

FIG. 9 illustrates the semiconductor device 1000 including five stacked structures, but this is an example. The semiconductor device 1000 according to the disclosure may include the plurality of stacked structures vertically stacked in four, eight, twelve, sixteen stacks, or the like.

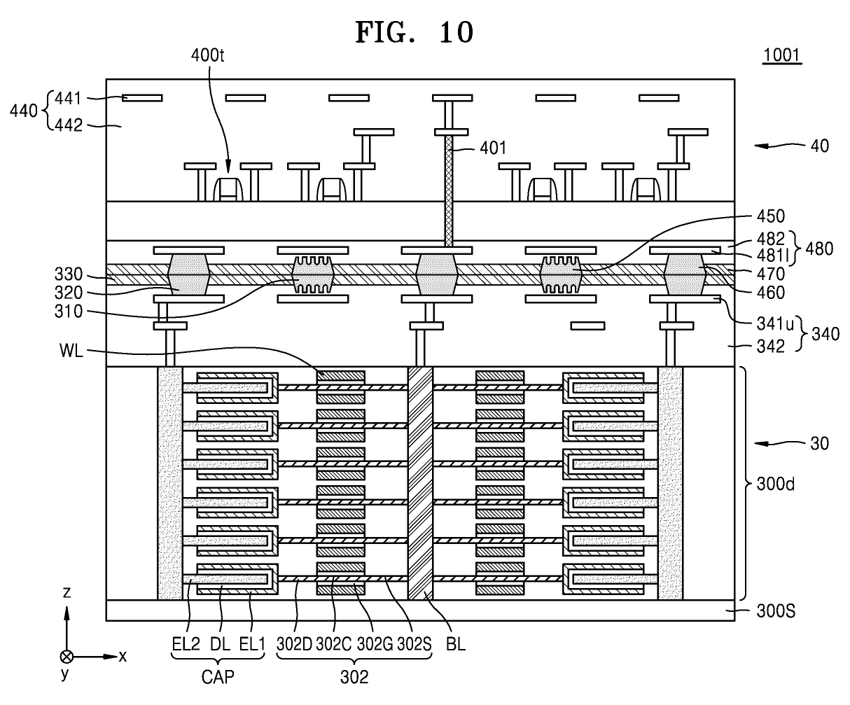

FIG. 10 is a cross-sectional view of a semiconductor device 1001 according to an embodiment.

Referring to FIG. 10, the semiconductor device 1001 may include a first stacked structure 30 and a second stacked structure 40 on the first stacked structure 30.

In some embodiments, the first stacked structure 30 may include a cell array structure (or a cell array chip), and the second stacked structure 40 may include a peripheral circuit structure (or a peripheral circuit chip). The cell array structure may include a plurality of memory cells, and the peripheral circuit structure may include a circuit for operating the plurality of memory cells.

The first stacked structure 30 may include a first semiconductor substrate 300s, a first semiconductor element layer 300d, a first upper wiring structure 340, a first upper bonding dielectric layer 330, a first upper dummy pad 310, and a first upper connection pad 320.

In some embodiments, the first semiconductor element layer 300d may include the plurality of memory cells vertically stacked. Each of the plurality of memory cells may include a memory cell transistor 302 and a capacitor CAP. The memory cell transistor 302 may include a source region 302S, a drain region 302D, a channel region 302C, and a gate 302G. At least a portion of an outer surface of the gate 302G may be surrounded by a word line WL, and at least a portion of an outer surface of the channel region 302C may be surrounded by the gate 302G. As an example, the memory cell transistor 302 may include a gate-all-around (GAA) transistor in which all outer surfaces of the channel region 302C are surrounded by the gate 302G. For example, the source region 302S of the memory cell transistor 302 may be connected to a bit line BL.

The capacitor CAP of the memory cell may include a first electrode EL1, a dielectric layer DL, and a second electrode EL2. The first electrode EL1 may be connected to the drain region 302D of the memory cell transistor 302. The first electrode EL1 and the second electrode EL2 may include a metal material, and the dielectric layer DL may include a high-k material. For example, the bit line BL may vertically penetrate from a top surface to a bottom surface of the first semiconductor element layer 300d.

Although FIG. 10 illustrates the plurality of memory cells stacked in six layers, the number of stacked memory cells is not limited to six, and the first stacked structure 30 may include memory cells stacked in various numbers of layers.

Although the first stacked structure 30 in FIG. 10 illustrates a 3D DRAM device in which DRAM elements are stacked in the vertical direction, this is an example, and the first stacked structure 30 may include various types of memory elements, such as a plurality of vertically stacked NAND flash elements.

The first upper wiring structure 340 may include a first uppermost wiring pattern 341u and a first upper wiring dielectric layer 342. The first upper wiring structure 340 may provide a path for an electrical signal in the vertical direction toward the first semiconductor element layer 300d, which is disposed below the first upper wiring structure 340 from above the first upper wiring structure 340.

A bottom surface of the first upper dummy pad 310 may be vertically spaced apart from the first uppermost wiring pattern 341u without contacting the first uppermost wiring pattern 341u. For example, a bottom surface of the first upper connection pad320 may be in contact with the first uppermost wiring pattern 341u. Sidewalls of the first upper dummy pad 310 and the first upper connection pad 320 may be surrounded by the first upper bonding dielectric layer 330.

The second stacked structure 40 may include a second semiconductor substrate 400s, a second peripheral transistor 400t on the second semiconductor substrate 400s, a second upper wiring structure 440, a second lower wiring structure 480, a second lower dummy pad 450, a second lower connection pad 460, and a second lower bonding dielectric layer 470.

The second upper wiring structure 440 may include a second upper wiring pattern 441 and a second upper wiring dielectric layer 442 surrounding the second upper wiring pattern 441. The second upper wiring pattern 441 may be connected to the second lower wiring structure 480 through a second through-electrode 401 that vertically penetrates the second semiconductor substrate 400s. The second peripheral transistor 400t may be electrically connected to the first stacked structure 30 through the second upper wiring structure 440, the second through-electrode 401, the second lower wiring structure 480, and the second lower connection pad 460.

The second lower wiring structure 480 may include a second lowermost wiring pattern 481l and a second lower wiring dielectric layer 482 surrounding the second lowermost wiring pattern 481l. The top surface of the second lower connection pad 460 may be in contact with the second lowermost wiring pattern 481l, while a top surface of the second lower dummy pad 450 may be vertically spaced apart from the second lowermost wiring pattern 481l without contacting the second lowermost wiring pattern 481l.

In some embodiments, the second lowermost wiring pattern 481l may include the second through-electrode 401. For example, the second lower wiring dielectric layer 482 may surround sidewalls of the second through-electrode 401. For example, the top surface of the second lower connection pad 460 may be in contact with the second through-electrode 401, while the top surface of the second lower dummy pad 450 may be vertically spaced apart from the second through-electrode 401 without contacting the second through-electrode 401.

The second lower dummy pad 450 and the second lower connection pad 460 of the second stacked structure 40 may be respectively disposed on the first upper dummy pad 310 and the first upper connection pad 320 of the first stacked structure 30. For example, the second lower bonding dielectric layer 470 of the second stacked structure 40 may be disposed on the first upper bonding dielectric layer 330 of the first stacked structure 30. For example, the first stacked structure 30 and the second stacked structure 40 may form a hybrid bonding structure.

Although FIG. 10 illustrates a Peri-on-Cell (POC) structure, in another example, the semiconductor device 1001 according to some embodiments may be implemented in a Cell-on-Peri (COP) structure. For example, the first stacked structure 30 may include a peripheral circuit structure, and the second stacked structure 40 may include a cell array structure.

Although FIG. 10 illustrates an example in which the semiconductor device 1001 is implemented as a memory device, the semiconductor device 1001 according to some embodiments may also be implemented as a three-dimensional (3D) complementary metal-oxide-semiconductor (CMOS) image sensor (3D CIS) device including a hybrid bonding structure, and may also be implemented as various types of devices.

The hybrid bonding structure described in detail with reference to FIGS. 8 to 10 may be formed based on wafer-to-wafer bonding. Inter-wafer bonding may refer to a technique for aligning a plurality of wafers with each other and bonding the plurality of wafers into a single structure, and may also be referred to as wafer-to-wafer bonding. As an example, the wafer-to-wafer bonding process may include maintaining a first wafer in a fixed state, aligning a second wafer with the first wafer, and placing the second wafer on the first wafer while maintaining the aligned state. After completing the inter-wafer bonding process and combining a plurality of wafers are combined into a single structure, a single independent device, e.g., the semiconductor device 1001 of FIG. 10, may be fabricated by performing a singulation process on the combined structure.

In the above example, it was described that the hybrid bonding structure may be formed based on wafer-to-wafer bonding, but this is an example. It will be understood that hybrid bonding structures according to one or more embodiments may also be formed based on a variety of processes, such as die-to-wafer bonding processes, die-to-die bonding processes, and the like.

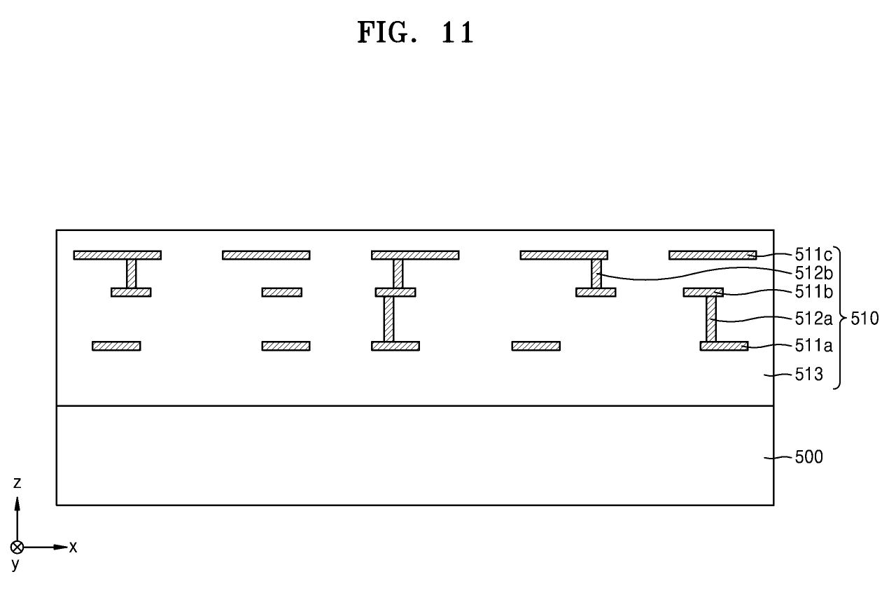

FIGS. 11 to 17 are diagrams for explaining a method of manufacturing a semiconductor device according to an embodiment.

Referring to FIG. 11, a wiring structure 510 may be formed on a semiconductor structure 500.

The wiring structure 510 may include a plurality of wiring line patterns 511a, 511b, and 511c, a plurality of wiring via-patterns 512a and 512b, and a wiring dielectric layer 513. The wiring dielectric layer 513 may surround the plurality of wiring line patterns 511a, 511b, and 511c and the plurality of wiring via-patterns 512a and 512b. The uppermost wiring line pattern 511c may be the wiring line pattern positioned at a highest position among the plurality of wiring line patterns 511a, 511b, and 511c. In some embodiments, each of the plurality of wiring line patterns 511a, 511b, and 511c and the plurality of wiring via-patterns 512a and 512b may be formed through a single damascene process. In other embodiments, the plurality of wiring line patterns 511a, 511b, and 511c and the plurality of wiring via-patterns 512a and 512b may be formed through a dual damascene process. For example, the second wiring line pattern 511b and the first wiring via-pattern 512a may be formed simultaneously, and the uppermost wiring line pattern 511c and the second wiring via-pattern 512b may be formed simultaneously.

The wiring dielectric layer 513 may include a plurality of dielectric material layers and a plurality of etch stop layers. In some embodiments, an etch stop layer including a nitride may be disposed on the uppermost wiring line pattern 511c, and a dielectric material layer including an oxide may be disposed on the etch stop layer. For example, the etch stop layer of the wiring dielectric layer 513 may include at least one of silicon nitride (SiN), silicon carbon nitride (SiCN), and aluminum nitride (AlN). However, the material forming the etch stop layer is not limited to the above examples. For example, the dielectric material layer of the wiring dielectric layer 513 may include at least one of silicon dioxide (SiO₂), silicon carbon oxygen hydrogen (SiCOH), and hafnium oxide (HfO₂). However, the material forming the dielectric material layer is not limited to the above examples. In some embodiments, the wiring dielectric layer 513 may not include the plurality of etch stop layers.

For example, each of the plurality of wiring line patterns 511a, 511b, and 511c and the plurality of wiring via-patterns 512a and 512b may further include a barrier layer to prevent diffusion of a metal material. However, in some embodiments, the plurality of wiring line patterns 511a, 511b, and 511c and the plurality of wiring via-patterns 512a and 512b may not include the barrier layer.

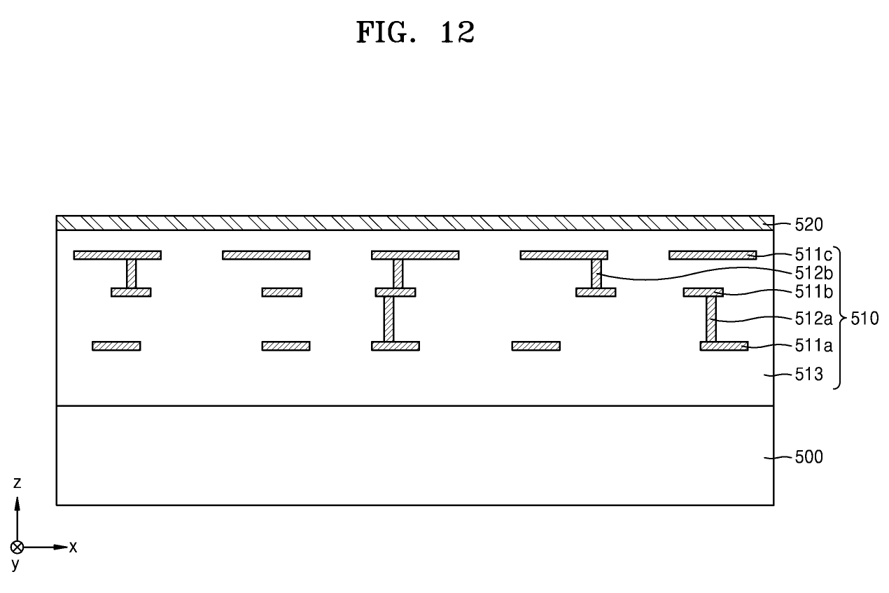

Referring to FIG. 12, a bonding dielectric layer 520 may be formed on the wiring structure 510.

In some embodiments, the bonding dielectric layer 520 may be formed through a deposition process. The deposition process may include at least one of a chemical vapor deposition (CVD) process, a PVD process, and an atomic layer deposition (ALD) process. In some embodiments, the bonding dielectric layer 520 may also be formed through a spin coating process.

A vertical thickness of the bonding dielectric layer 520 may be smaller than a vertical thickness of the wiring dielectric layer 513. In some embodiments, the vertical thickness of the bonding dielectric layer 520 may be about several nm to about several hundred nm. In some embodiments, the vertical thickness of the bonding dielectric layer 520 may be about several μm to about several hundred μm. In some embodiments, the bonding dielectric layer 520 and the wiring dielectric layer 513 may include the same material. In some embodiments, the bonding dielectric layer 520 may include a material different from the material of the wiring dielectric layer 513.

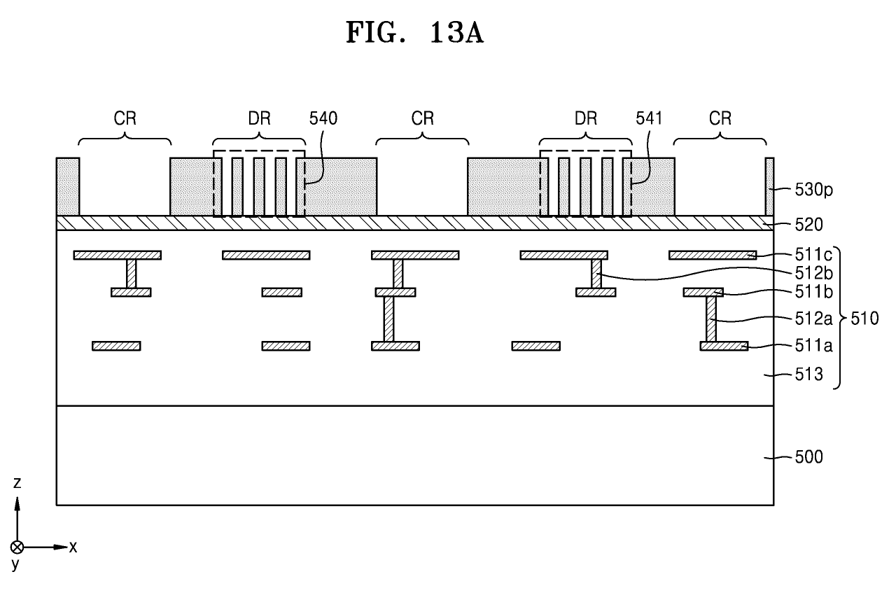

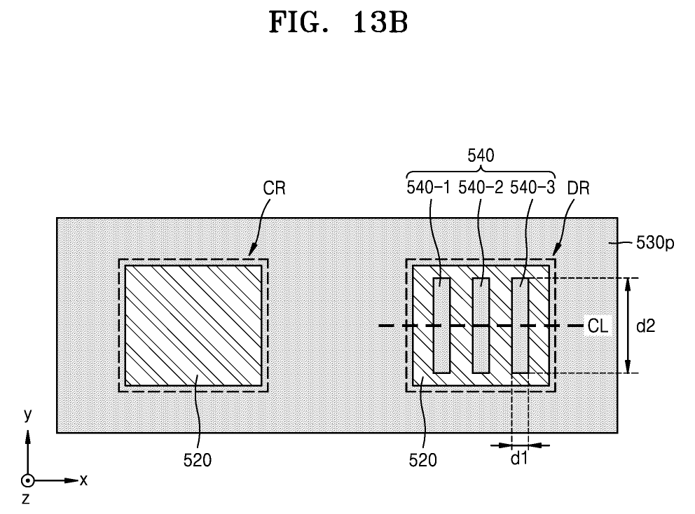

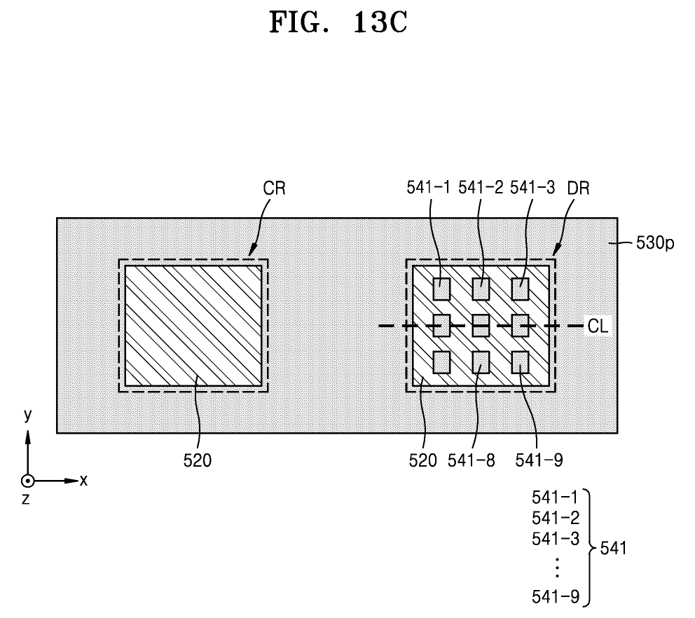

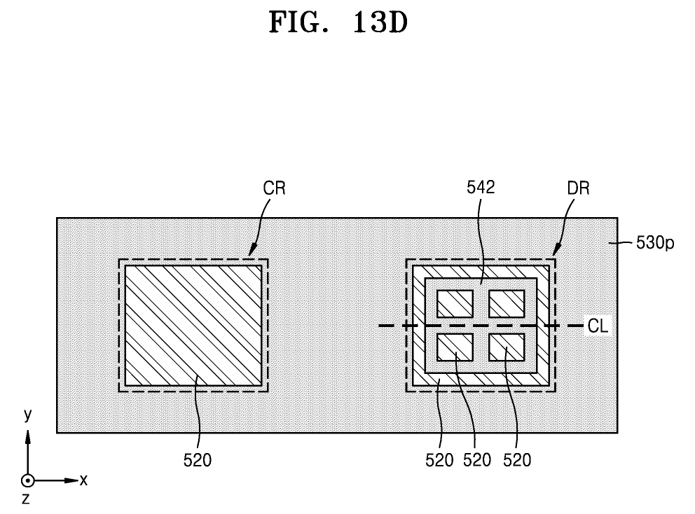

Referring to FIG. 13A, a patterned photoresist layer 530p may be formed on the bonding dielectric layer 520.

According to some embodiments, a photoresist layer may be formed on the bonding dielectric layer 520. The photoresist layer may be formed by the spin coating process. However, the photoresist layer may also be formed by various processes other than the spin coating process.

Subsequently, the photoresist layer formed on the bonding dielectric layer 520 may be patterned. The photoresist layer may be patterned through exposure and development processes. The patterned photoresist layer 530p may include first and second fine photoresist pattern structures 540 and 541.

In some embodiments, when the photoresist layer is patterned, the photoresist layer in a connection region CR may be removed (e.g., completely removed), while only a portion of the photoresist layer in a dummy region DR may be removed. After the patterning is performed, a remaining photoresist layer in the dummy region DR may form the first and second fine photoresist pattern structures 540 and 541. In the disclosure, the connection region CR may be a region defined for forming a connection pad CP, and may refer to a region that vertically overlaps a position where the connection pad CP is to be formed in a subsequent process. For example, in the disclosure, the dummy region DR may refer to a region defined for forming a dummy pad DP, which is an area that vertically overlaps a position where the dummy pad DP is to be formed in a subsequent process.

The first and second fine photoresist pattern structures 540 and 541 may include photoresist patterns of various structures and will be described in detail with reference to FIGS. 13B to 13D.

FIGS. 13B to 13D are top plan views of the patterned photoresist layer 530p according to some embodiments.

Referring to FIG. 13B, the first fine photoresist pattern structure 540 may include a plurality of first photoresist bars 540-1, 540-2, and 540-3. The plurality of first photoresist bars 540-1, 540-2, and 540-3 may be formed to protrude in the upward direction from a top surface of the bonding dielectric layer 520.

In the dummy region DR, an area of the bonding dielectric layer 520 exposed upward by the patterned photoresist layer 530p may be a first exposed area. In the connection region CR, the area of the bonding dielectric layer 520 exposed upward by the patterned photoresist layer 530p may be a second exposed area. The first exposed area may be greater than the second exposed area.

For example, a first shape defined by an outer boundary of the bonding dielectric layer 520 exposed upward in the dummy region DR by the patterned photoresist layer 530p may be the same as a second shape defined by an outer boundary of the bonding dielectric layer 520 exposed upward in the connection region CR by the patterned photoresist layer 530p. The outer boundary of the bonding dielectric layer 520 may appear as a boundary between the patterned photoresist layer 530p and the bonding dielectric layer 520 when viewed from above.

In some embodiments, as shown in FIG. 13B, the first shape and the second shape may be the same rectangle and may have the same area (or same size). In some embodiments, the first shape and the second shape may be oval or circular, and in this case as well, the first shape and the second shape may have the same area (or same size).

The plurality of first photoresist bars 540-1, 540-2, and 540-3 may be spaced apart from each other in the horizontal direction (e.g., x-axis direction). In some embodiments, as shown in FIG. 13B, the plurality of first photoresist bars 540-1, 540-2, and 540-3 may be spaced apart from each other in the first horizontal direction (e.g., x-axis direction) and may have a shape elongated in the second horizontal direction (e.g., y-axis direction). Each of the plurality of first photoresist bars 540-1, 540-2, and 540-3 may have a first horizontal width d1 in the first horizontal direction and a second horizontal width d2 in the second horizontal direction. The second horizontal width d2 may be greater than the first horizontal width d1. In some embodiments, unlike the example shown in FIG. 13B, the plurality of first photoresist bars 540-1, 540-2, and 540-3 may be spaced apart from each other in the second horizontal direction and may have shapes elongated in the first horizontal direction. For example, the first horizontal width d1may be greater than the second horizontal width d2.

In some embodiments, the plurality of first photoresist bars 540-1, 540-2, and 540-3 may be arranged in a mirror-symmetric structure with respect to a horizontal center line CL. The horizontal center line may refer to a line that bisects (or intersects), in the horizontal direction, the bonding dielectric layer 520 exposed upward in the dummy region DR. However, the arrangement of the plurality of first photoresist bars 540-1, 540-2, and 540-3 is not limited to the above example and may not be in the mirror-symmetric structure.

FIG. 13B illustrates that the plurality of first photoresist bars 540-1, 540-2, and 540-3 includes three bars, but this is an example, and the number of the plurality of first photoresist bars 540-1, 540-2, and 540-3 may be four or more, or two or less, and as such, the number of the plurality of first photoresist bars 540-1, 540-2, and 540-3 may be implemented in various numbers.

Referring to FIG. 13C, the second fine photoresist pattern structure 541 may include a plurality of second photoresist bars 541-1, 541-2, 541-3, ..., and 541-9.

In some embodiments, as shown in FIG. 13C, the plurality of second photoresist bars 541-1, 541-2, 541-3, ..., and 541-9 may be spaced apart from each other in both the first and second horizontal directions. In some embodiments, the plurality of second photoresist bars 541-1, 541-2, 541-3, ..., and 541-9 may be arranged in the mirror-symmetric structure with respect to the horizontal center line CL. However, the arrangement of the plurality of second photoresist bars 541-1, 541-2, 541-3, ..., and 541-9 is not limited to the above example, and as such, the arrangement of the plurality of second photoresist bars 541-1, 541-2, 541-3, ..., and 541-9 may not be in the mirror-symmetric structure. Although FIG. 13C illustrates that the plurality of second photoresist bars 541-1, 541-2, 541-3, ..., and 541-9 are nine in number, this is an example, and the plurality of second photoresist bars 541-1, 541-2, 541-3, ..., and 541-9 may be implemented in various numbers such as four, sixteen, or twenty-five.

Referring to FIG. 13D, the patterned photoresist layer 530p may include a third fine photoresist pattern structure 542. In some embodiments, the third fine photoresist pattern structure 542 may be arranged in the mirror-symmetric structure with respect to the horizontal center line CL. However, the third fine photoresist pattern structure 542 may not be arranged in the mirror-symmetric structure. For example, the arrangement structure of the third fine photoresist pattern structure 542 is not limited to the examples described above.

In top plan view as shown in FIG. 13D, the bonding dielectric layer 520 and the third fine photoresist pattern structure 542 may be alternately arranged along the horizontal direction. In plan view, the bonding dielectric layer 520 may be arranged in an island shape surrounded by the third fine photoresist pattern structure 542.

As seen in FIGS. 13B to 13D, in top plan view, the first shape defined by the outer boundary of the bonding dielectric layer 520 exposed upward in the dummy region DR may be the same as the second shape defined by the outer boundary of the bonding dielectric layer 520 exposed upward in the connection region CR. Accordingly, the shape and the area of the top surface of the dummy pad DP and the connection pad CP formed in a subsequent process may be the same as each other.

As seen in FIGS. 13B to 13D, the patterned photoresist layer 530p may include the first to third fine photoresist pattern structures 540, 541, and 542. Accordingly, a connection opening CO formed in a subsequent process may expose the uppermost wiring line pattern 511c upward, while a dummy opening DO may not expose the uppermost wiring line pattern 511c upward.

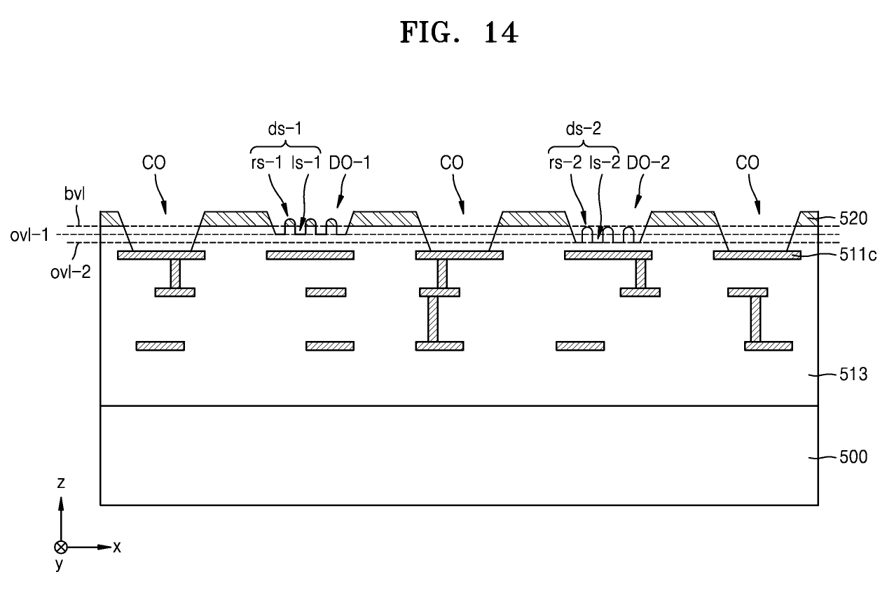

Referring to FIG. 14, dummy openings DO-1 and DO-2 and the connection openings CO penetrating the bonding dielectric layer 520 in the vertical direction may be formed.

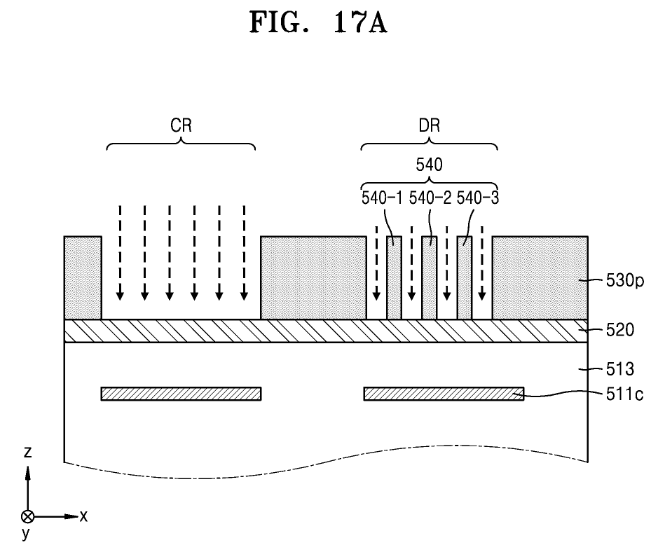

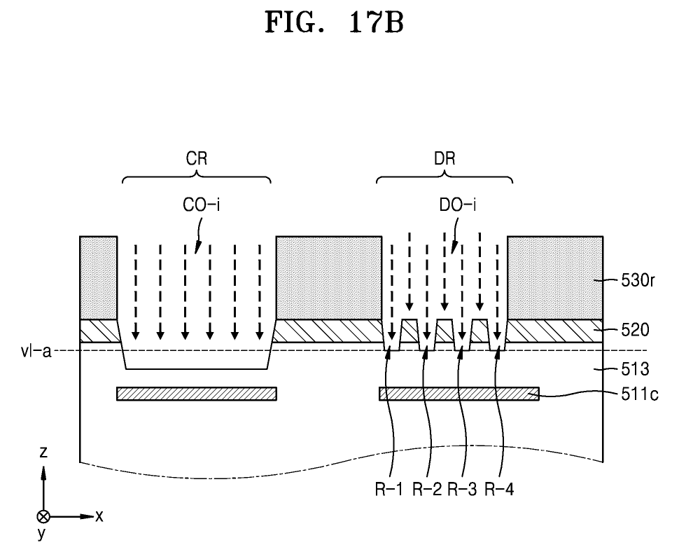

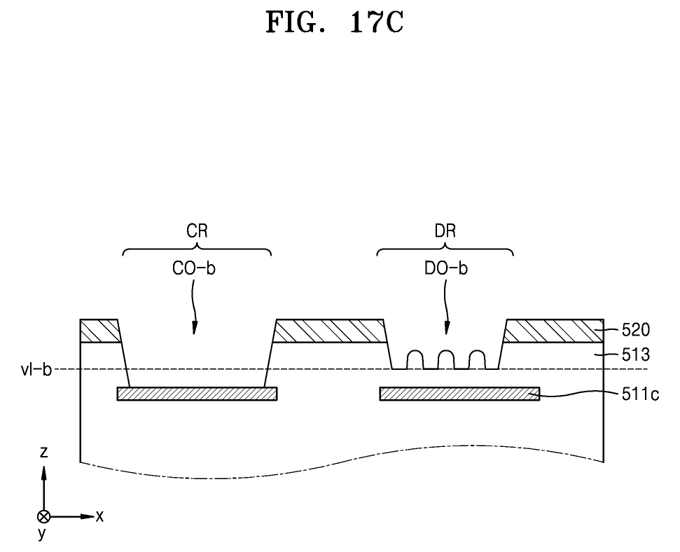

According to some embodiments, the connection openings CO and the dummy openings DO-1 and DO-2 may be formed through an etching process using the patterned photoresist layer 530p of FIG. 13A as an etch mask. In the dummy region DR, the patterned photoresist layer 530p may include the fine photoresist pattern structures 540 and 541, while no photoresist material may be disposed in the connection region CR. In the etching process, thin photoresist bars included in the fine photoresist pattern structures 540 and 541 may not function as an etch mask. For example, during the etching process, the plurality of photoresist bars may be removed. The process in which the plurality of photoresist bars are removed during the etching process will be described in detail with reference to FIGS. 17A, 17B, and 17C below.

As shown in FIG. 14, the connection opening CO may expose the uppermost wiring line pattern 511c, the wiring dielectric layer 513, and the bonding dielectric layer 520 upward. For example, the dummy openings DO-1 and DO-2 may not expose the uppermost wiring line pattern 511c upward. The dummy openings DO-1 and DO-2 may expose the wiring dielectric layer 513 and the bonding dielectric layer 520 upward.

In some embodiments, the dummy openings DO-1 and DO-2 may expose respective dummy surfaces ds-1 and ds-2 upward. The dummy surface may refer to a surface of the wiring dielectric layer 513 and/or a surface of the bonding dielectric layer 520 that is exposed by the dummy openings DO-1 and DO-2. For example, a first dummy surface ds-1 may include the surface of the wiring dielectric layer 513 and the surface of the bonding dielectric layer 520, which are exposed upward by the first dummy opening DO-1. As another example, the second dummy surface ds-2 may include the surface of the wiring dielectric layer 513 and the surface of the bonding dielectric layer 520, which are exposed upward by the second dummy opening DO-2.

According to some embodiments, the first dummy surface ds-1 may include a first lowest surface ls-1 and a first raised surface rs-1. The first lowest surface ls-1 may refer to a surface that is positioned at a lowest vertical level among the entire surface of the first dummy surface ds-1. For example, the first raised surface rs-1 may refer to a surface that is connected to the first lowest surface ls-1 and protrudes upward from the first lowest surface ls-1 among the entire surface of the first dummy surface ds-1. Similarly to the above, the second dummy surface ds-2 may also include a second lowest surface ls-2 and a second raised surface rs-2 that protrudes upward from the second lowest surface ls-2.

According to some embodiments, horizontal positions of each of a plurality of first raised surfaces rs-1 may correspond to horizontal positions of each of the plurality of first photoresist bars 540-1, 540-2, and 540-3 included in the first fine photoresist pattern structure 540 of FIG. 13A. For example, the positions of each of the plurality of first raised surfaces rs-1 may vertically overlap the positions of each of the plurality of first photoresist bars 540-1, 540-2, and 540-3. For example, a degree of upward protrusion of the plurality of first raised surfaces rs-1 may be determined based on horizontal widths of the plurality of first photoresist bars 540-1, 540-2, and 540-3. For example, the larger the horizontal width of the photoresist bar, the greater the degree of the upward protrusion of the raised surface formed at the horizontal position consistent with the horizontal position of the photoresist bar.

For example, the horizontal width of the first photoresist bar 540-1 in FIG. 13B is greater than the horizontal width of the second photoresist bar 541-1 in FIG. 13C. Accordingly, a first degree of upward protrusion of the first raised surface rs-1 formed at a position corresponding to the horizontal position of the first photoresist bar 540-1 may be greater than a second degree of upward protrusion of the second raised surface rs-2 formed at a position corresponding to the horizontal position of the second photoresist bar 541-1.

In some embodiments, the first raised surface rs-1 may include the surface of the wiring dielectric layer 513 and the surface of the bonding dielectric layer 520. The surface of the wiring dielectric layer 513 and the surface of the bonding dielectric layer 520 included in the first raised surface rs-1 may form a continuous surface. For example, the surface of the wiring dielectric layer 513 included in the first raised surface rs-1 may be positioned in a lower portion of the first raised surface rs-1, and the surface of the bonding dielectric layer 520 included in the first raised surface rs-1 may be positioned in an upper portion of the first raised surface rs-1. The upper portion and the lower portion of the first raised surface rs-1 may be distinguished (or defined) based on a bonding vertical level bvl. The bonding vertical level bvl may refer to a vertical level at which a bottom surface of the bonding dielectric layer 520 may be positioned.

In some embodiments, the second raised surface rs-2 may include only the surface of the wiring dielectric layer 513. According to some embodiments, the first raised surface rs-1 and the second raised surface rs-2 may include convex surfaces protruding in the upward direction, and the first raised surface rs-1 may have the mirror-symmetric structure with respect to a central axis of the first raised surface rs-1.

In some embodiments, a first vertical level ovl-1 of the first lowest surface ls-1 may be determined based on the first exposed area described in FIG. 13B. As described above, the first exposed area may refer to the area of the bonding dielectric layer 520 that is exposed upward in the dummy region DR by the patterned photoresist layer 530p. As the first exposed area increases, the first vertical level ovl-1 of the first lowest surface ls-1 may decrease, and as the first exposed area decreases, the first vertical level ovl-1 of the first lowest surface ls-1 may increase.

For example, the area of the bonding dielectric layer 520 exposed upward by the first fine photoresist pattern structure 540 of FIG. 13B is smaller than the area of the bonding dielectric layer 520 exposed upward by the second fine photoresist pattern structure 541 of FIG. 13C. The first vertical level ovl-1 of the first lowest surface ls-1 formed by performing an etching process using the first fine photoresist pattern structure 540 as an etching mask is higher than a second vertical level ovl-2 of the second lowest surface ls-2 formed by performing an etching process using the second fine photoresist pattern structure 541 as an etching mask.

As described above, by adjusting the exposed area of the bonding dielectric layer exposed upward by the fine photoresist pattern structure, a vertical level at which the dummy opening is formed may be adjusted. For example, by adjusting the horizontal width of the photoresist bar, the protrusion degree of the raised surface exposed by a dummy opening formed through the etching process may be adjusted.

As a result, a volume of the dummy opening formed by the etching process may be determined based on a shape of the fine photoresist pattern structure. For example, a mass of a metal material forming the dummy pad may be determined based on a volume of the dummy opening. The dummy pad is the metal pad formed to fill the dummy opening in a subsequent process. For example, as the volume of the dummy opening increases, the mass of the metal material forming the dummy pad may increase, and as the volume of the dummy opening decreases, the mass of the metal material may decrease. By adjusting the mass of the metal material, the warpage phenomenon, which is caused by the number of stacked layers increases, may be prevented, and the reliability of metal-to-metal bonding included in the hybrid bonding structure may be improved.

For example, based on the shape of the fine photoresist pattern structure, a parasitic capacitance value between the dummy pad and the uppermost wiring line pattern 511c may be adjusted. For example, when a dielectric constant of the wiring dielectric layer 513 is high, an increase in a parasitic capacitance value between the dummy pad filling the first dummy opening DO-1 and the uppermost wiring line pattern 511c may need to be prevented. For example, the first exposed area of the bonding dielectric layer 520, which is exposed upward by the first fine photoresist pattern structure 540, may be reduced, and as the first exposed area decreases, a vertical level of the first lowest surface ls-1 exposed by the first dummy opening DO-1 may increase. As a result, a distance between the dummy pad filling the first dummy opening DO-1 and the uppermost wiring line pattern 511c may increase, and the increase in parasitic capacitance between the dummy pad and the uppermost wiring line pattern 511c may be prevented.

For example, photoresist materials disposed on the bonding dielectric layer 520 may be entirely removed after the etching process is performed. The removal of the photoresist materials may be performed through a strip process. In some embodiments, plasma ashing may be performed to remove the photoresist materials.

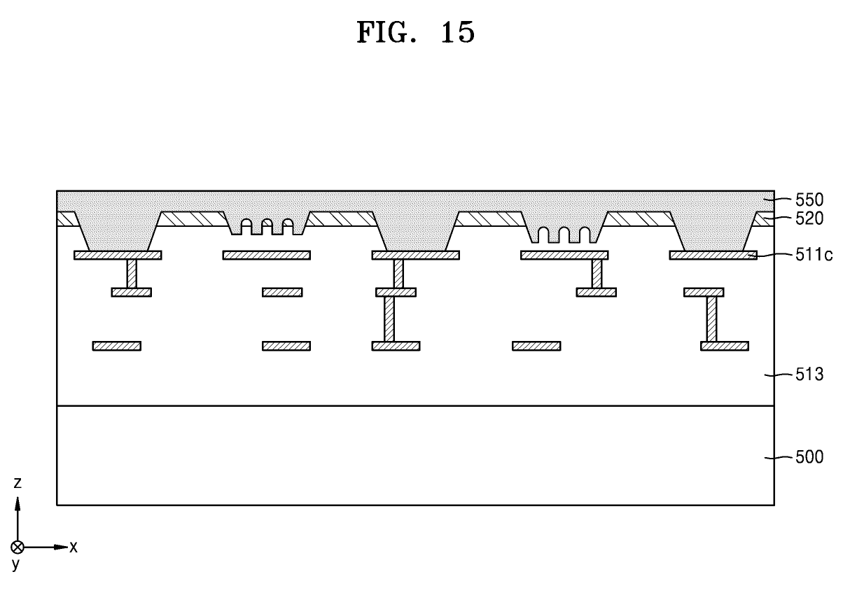

Referring to FIG. 15, a metal material layer 550 may be formed to fill the dummy openings and the connection openings and be disposed on the bonding dielectric layer 520.

In some embodiments, a barrier layer may be formed in the dummy openings DO-1 and DO-2 and the connection openings CO of FIG. 14. The barrier layer may be formed on surfaces of the bonding dielectric layer 520 and the wiring dielectric layer 513 that are exposed upward by each of the dummy openings DO-1 and DO-2 and the connection openings CO. For example, the barrier layer may be formed on the surface of the uppermost wiring line pattern 511c, which is exposed upward by the connection opening CO. The barrier layer may include copper (Cu), titanium (Ti), titanium tungsten (TiW), titanium nitride (TiN), tantalum (Ta), tantalum nitride (TaN), chromium (Cr), aluminum (Al), or a combination thereof. Forming of the barrier layer may be performed through a plating process, a PVD process, or a CVD process, but is not limited thereto.

In some embodiments, the metal material layer 550 may fill the dummy openings DO-1 and DO-2 and the connection openings CO and may cover the top surface of the bonding dielectric layer 520. The metal material layer 550 may include a metal or a metal alloy such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), but is not limited thereto. Forming the metal material layer 550 may be performed through a plating process, a PVD process, or a CVD process, but is not limited thereto.

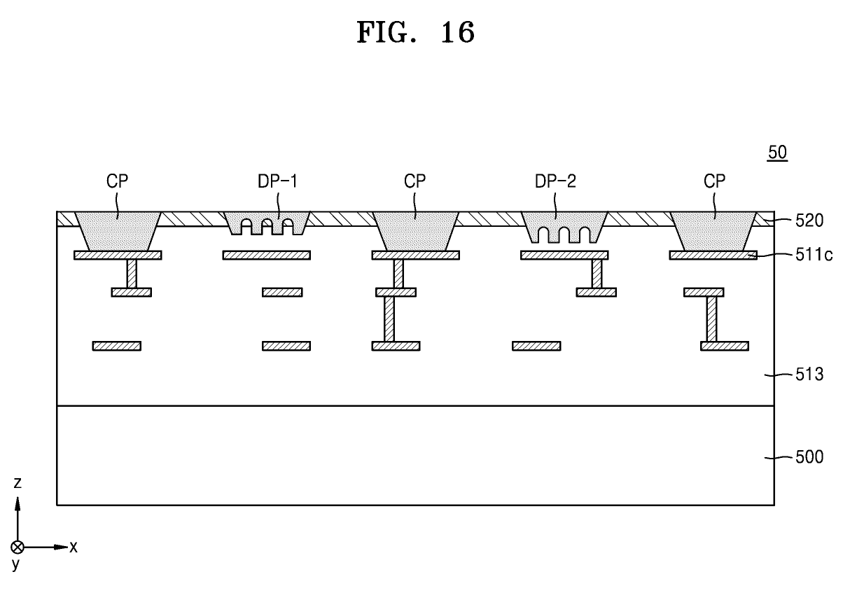

Referring to FIG. 16, a portion of the metal material layer 550 may be removed to form dummy pads DP-1 and DP-2 and the connection pad CP.

In some embodiments, a planarization process may be performed on the metal material layer 550 of FIG. 15. The planarization process may be performed until the top surface of the bonding dielectric layer 520 is exposed upward. By performing the planarization process, an upper portion of the metal material layer 550 may be removed. For example, the planarization process may include a chemical mechanical polishing (CMP) process.

Upon completion of the planarization process, the connection pad CP and the dummy pads DP-1 and DP-2 may be formed. A bottom surface of the connection pad CP may be in contact with the uppermost wiring line pattern 511c, while bottom surfaces of the dummy pads DP-1 and DP-2 may not be in contact with the uppermost wiring line pattern 511c, and may be in contact with the wiring dielectric layer 513 and/or the bonding dielectric layer 520 and may be surrounded by the wiring dielectric layer 513 and/or the bonding dielectric layer 520. A top surface of the connection pad CP and each of top surfaces of the dummy pads DP-1 and DP-2 may be exposed upward. The top surface of the connection pad CP and the top surfaces of the dummy pads DP-1 and DP-2 may have the same shape.

A mass of the metal material forming the connection pad CP may be different from the mass of the metal material forming each of the dummy pads DP-1 and DP-2. For example, the mass of the metal material forming the first dummy pad DP-1 and the mass of the metal material forming the second dummy pad DP-2 may also be different from each other. For example, the mass of the metal material forming the first dummy pad DP-1 may be smaller than the mass of the metal material forming the second dummy pad DP-2.

FIGS. 17A, 17B, and 17C are cross-sectional views for illustrating a method of performing an etching process according to an embodiment.

Referring to FIG. 17A, a first etching process may be performed by using the patterned photoresist layer 530p as an etching mask. In some embodiments, the first etching process may be a dry etching process.

The patterned photoresist layer 530p may include the first fine photoresist pattern structure 540 disposed in the dummy region DR. The first fine photoresist pattern structure 540 may include the plurality of first photoresist bars 540-1, 540-2, and 540-3. By performing the first etching process, a portion of the bonding dielectric layer 520 and the plurality of first photoresist bars 540-1, 540-2, and 540-3 may be removed.

In the dummy region DR, the portion of the bonding dielectric layer 520, removed by performing the first etching process, may not overlap each of the plurality of first photoresist bars 540-1, 540-2, and 540-3 in the vertical direction. For example, in the dummy region DR, a remaining portion of the bonding dielectric layer 520, not removed by performing the first etching process, may overlap each of the plurality of first photoresist bars 540-1, 540-2, and 540-3 in the vertical direction. For example, until the first fine photoresist pattern structure 540 is removed by performing the first etching process, a portion of the bonding dielectric layer 520 disposed at a location (or area) overlapping the first fine photoresist pattern structure 540 in the vertical direction may not be removed.

Referring to FIG. 17B, a second etching process may be performed by using a remaining photoresist layer 530r as an etching mask. FIG. 17B illustrates an intermediate dummy opening DO-i and an intermediate connection opening CO-i formed by performing the first etching process.

Each of the intermediate dummy opening DO-i and the intermediate connection opening CO-i refers to an opening, formed by performing the first etching process and existing temporarily before performing the second etching process, and does not refer to an opening finally formed through the etching process. The intermediate dummy opening DO-i and the intermediate connection opening CO-i may each refer to a space surrounded by the remaining photoresist layer 530r, the bonding dielectric layer 520, and/or the wiring dielectric layer 513 and exposed upward.

By performing the first etching process, the first fine photoresist pattern structure 540 of FIG. 17A may be removed. For example, the intermediate dummy opening DO-i may include a plurality of recesses (e.g., first to fourth recesses R-1, R-2, R-3, and R-4). The intermediate connection opening CO-i may be formed to be deeper in the downward direction than the intermediate dummy opening DO-i.

In some embodiments, as shown in FIG. 17B, a low-end vertical level vl-a of the first to fourth recesses R-1, R-2, R-3, and R-4 formed by performing the first etching process may be lower than a vertical level of a bottom surface of the bonding dielectric layer 520. In some embodiments, the low-end vertical level vl-a may be higher than the vertical level of the bottom surface of the bonding dielectric layer 520 and lower than the vertical level of the top surface of the bonding dielectric layer 520. In some embodiments, the low-end vertical level vl-a may be substantially equal to the vertical level of the bottom surface of the bonding dielectric layer 520.

Although FIG. 17B illustrates that the intermediate dummy opening DO-i includes the first to fourth recesses R-1, R-2, R-3, and R-4, the number of recesses included in the intermediate dummy opening DO-i may, of course, be three or fewer, five or more, or implemented in various numbers.

FIG. 17B illustrates that low-end vertical levels of the first to fourth recesses R-1, R-2, R-3, and R-4 included in the intermediate dummy opening DO-i may be the same as each other, but this is an example. The low-end vertical level vl-a of the first to fourth recesses R-1, R-2, R-3, and R-4 may all be different, or only some may be the same, and various implementations are possible.

The second etching process may be an etching process that uses the remaining photoresist layer 530r as an etching mask. The remaining photoresist layer 530r may be a photoresist layer from which all fine photoresist pattern structures have been removed from the patterned photoresist layer 530p of FIG. 17A. For example, the first etching process and the second etching process may be the same type of etching process. For example, the first etching process and the second etching process may both be dry etching processes using chlorine gas.

Referring to FIG. 17C, a connection opening CO-b and a dummy opening DO-b may be formed by removing the photoresist layers and exposing the bonding dielectric layer 520 and the wiring dielectric layer 513 upward. FIG. 17C illustrates the connection opening CO-b and the dummy opening DO-b after the second etching process is performed and after all of the photoresist material on the bonding dielectric layer 520 and the wiring dielectric layer 513 is removed.

The connection opening CO-b formed through the second etching process may expose the uppermost wiring line pattern 511c upward, and the dummy opening DO-b may expose the wiring dielectric layer 513 upward.

In some embodiments, a low-end vertical level vl-b of the dummy opening DO-b may be higher than a vertical level of the uppermost wiring line pattern 511c and lower than the vertical level of the bottom surface of the bonding dielectric layer 520. In another embodiment, the low-end vertical level vl-b of the dummy opening DO-b may be substantially equal to the vertical level of the bottom surface of the bonding dielectric layer 520 or may be higher than the vertical level of the bottom surface of the bonding dielectric layer 520.

Also, as described in FIG. 14, the surface of the wiring dielectric layer 513 and/or the surface of the bonding dielectric layer 520 exposed upward by the dummy opening DO-b may include a plurality of raised surfaces protruding in the upward direction.

As described with reference to FIGS. 17A, 17B, and 17C, a longer execution time of the first etching process may result in a greater degree of upward protrusion of the raised surface exposed by the dummy opening DO-b. For example, a longer execution time of the first etching process may result in a lower low-end vertical level vl-b of the dummy opening DO-b. The duration of the first etching process may be determined by the shape of the first fine photoresist pattern structure 540 of FIG. 17A. For example, the greater a horizontal width of the first photoresist bar 540-1 included in the first fine photoresist pattern structure 540, the longer the duration of the first etching process may be, whereas the smaller the horizontal width of the first photoresist bar 540-1, the shorter the duration of the first etching process may be. Ultimately, by diversely designing the fine photoresist pattern structure, embossing structures of various shapes may be formed on the bottom surface of the dummy pad, thereby preventing the dummy pad from coming into contact with the uppermost wiring pattern. For example, as the patterned photoresist layer 530p includes the fine photoresist pattern structure, both the connection opening CO and the dummy openings DO-1 and DO-2 may be formed by performing a single photolithography process. Ultimately, a photolithography process for forming the connection opening CO and a photolithography process for forming the dummy opening DO may not need to be separately performed.

While the disclosure has been particularly shown and described with reference to embodiments thereof, it will be understood that various changes in form and details may be made therein without departing from the spirit and scope of the following claims.

What is claimed is:

1. A semiconductor device comprising:
a semiconductor structure comprising a semiconductor substrate and a semiconductor element layer;
a wiring structure on the semiconductor structure;
a bonding dielectric layer on the wiring structure;
a connection pad penetrating the bonding dielectric layer from a top surface of the bonding dielectric layer in a downward direction and having sidewalls surrounded by the bonding dielectric layer; and
a dummy pad penetrating at least a portion of the bonding dielectric layer from the top surface of the bonding dielectric layer in the downward direction and having sidewalls surrounded by the bonding dielectric layer,
wherein a bottom surface of the dummy pad is at a higher vertical level than a bottom surface of the connection pad, and
wherein the bottom surface of the dummy pad comprises a plurality of surfaces at different vertical levels.

2. The semiconductor device of claim 1, wherein a top surface of the dummy pad and a top surface of the connection pad have a same shape, and
a surface size of the bottom surface of the dummy pad is greater than a surface size of the bottom surface of the connection pad.

3. The semiconductor device of claim 1, wherein the wiring structure comprises an uppermost wiring pattern and a wiring dielectric layer surrounding the uppermost wiring pattern,
the bottom surface of the connection pad is in contact with the uppermost wiring pattern,
the bottom surface of the dummy pad is in contact with the wiring dielectric layer, and
a vertical level of the bottom surface of the dummy pad is higher than a vertical level of the uppermost wiring pattern.

4. The semiconductor device of claim 3, wherein a portion of the bottom surface of the dummy pad is in contact with the wiring dielectric layer, and
a remaining portion of the bottom surface of the dummy pad is in contact with the bonding dielectric layer.

5. The semiconductor device of claim 1, wherein the bottom surface of the dummy pad comprises a lowest surface and a raised surface, and
the raised surface protrudes from the lowest surface in an upward direction.

6. The semiconductor device of claim 5, wherein the raised surface comprises a convex surface and a sloped surface that are convex in the upward direction,
the sloped surface is between the convex surface and the lowest surface in a vertical cross-section cut vertically along a horizontal line dividing the top surface of the dummy pad,
the sloped surface is inclined in the vertical cross-section to be farther away from a central axis of the convex surface as the sloped surface goes in the downward direction, and
the central axis of the convex surface comprises a vertical line passing through a center of the convex surface.

7. The semiconductor device of claim 6, wherein the wiring structure comprises an uppermost wiring pattern and a wiring dielectric layer surrounding the uppermost wiring pattern, and
the lowest surface and the sloped surface are in contact with the wiring dielectric layer.

8. The semiconductor device of claim 7, wherein a portion of the sloped surface is in contact with the wiring dielectric layer,
a remaining portion of the sloped surface is in contact with the bonding dielectric layer, and
the convex surface is surrounded by the bonding dielectric layer.

9. The semiconductor device of claim 7, wherein a portion of the convex surface is in contact with the wiring dielectric layer, and
a remaining portion of the convex surface is surrounded by the bonding dielectric layer.

10. A semiconductor device comprising:
a semiconductor structure comprising a semiconductor substrate and a semiconductor element layer;
a wiring structure under the semiconductor structure;
a bonding dielectric layer under the wiring structure;
a connection pad penetrating the bonding dielectric layer from a bottom surface of the bonding dielectric layer in an upward direction and having sidewalls surrounded by the bonding dielectric layer; and
a dummy pad penetrating at least a portion of the bonding dielectric layer from the bottom surface of the bonding dielectric layer in the upward direction and having sidewalls surrounded by the bonding dielectric layer,
wherein a top surface of the dummy pad is at a vertical level lower than a top surface of the connection pad, and
wherein the top surface of the dummy pad comprises a plurality of surfaces at different vertical levels.

11. The semiconductor device of claim 10, wherein the bottom surface of the dummy pad and the bottom surface of the connection pad have a same shape, and
a surface size of the top surface of the dummy pad is larger than a surface size of the top surface of the connection pad.

12. The semiconductor device of claim 10, wherein the wiring structure comprises a lowermost wiring pattern and a wiring dielectric layer surrounding the lowermost wiring pattern,
wherein the top surface of the connection pad is in contact with the lowermost wiring pattern,
wherein the top surface of the dummy pad is in contact with the wiring dielectric layer, and
wherein a vertical level of the top surface of the dummy pad is lower than a vertical level of the lowermost wiring pattern.

13. The semiconductor device of claim 12, wherein the top surface of the dummy pad comprises a highest surface and a recessed surface, and
wherein the recessed surface is recessed from the highest surface in a downward direction.

14. The semiconductor device of claim 13, wherein, in a horizontal cross-section of the dummy pad cut by a horizontal plane dividing the recessed surface, the dummy pad and the wiring dielectric layer are alternately arranged.

15. The semiconductor device of claim 14, wherein, in the horizontal cross-section, the dummy pads are arranged mirror-symmetrically with respect to a centerline,
wherein in the horizontal cross-section, the wiring dielectric layer is arranged mirror-symmetrically with respect to the centerline, and
wherein in the horizontal cross-section, the centerline is a horizontal line that bisects the dummy pad.

16. The semiconductor device of claim 13, wherein, in a horizontal cross-section of the dummy pad cut along a horizontal plane at a first vertical level dividing the recessed surface, the dummy pad and the wiring dielectric layer are alternately arranged,
wherein in the horizontal cross-section of the dummy pad cut along a horizontal plane at a second vertical level dividing the recessed surface, the dummy pad and the bonding dielectric layer are alternately arranged, and
wherein the second vertical level is lower than the first vertical level.

17. A semiconductor device comprising a plurality of stacked structures stacked in a vertical direction and comprising a first stacked structure and a second stacked structure disposed on the first stacked structure,
wherein an upper structure of the first stacked structure comprises:
a first bonding dielectric layer;
a first connection pad penetrating the first bonding dielectric layer in a downward direction from a top surface of the first bonding dielectric layer; and
a first dummy pad penetrating at least a portion of the first bonding dielectric layer in the downward direction from the top surface of the first bonding dielectric layer,
wherein a lower structure of the second stacked structure comprises:
a second bonding dielectric layer;
a second connection pad penetrating the second bonding dielectric layer in an upward direction from a bottom surface of the second bonding dielectric layer and disposed on the first connection pad; and
a second dummy pad penetrating at least a portion of the second bonding dielectric layer in the upward direction from the bottom surface of the second bonding dielectric layer and disposed on the first dummy pad,
wherein at least one of a bottom surface of the first dummy pad and a top surface of the second dummy pad comprises an embossed structure, and
wherein the embossed structure comprises a plurality of surfaces at different vertical levels.

18. The semiconductor device of claim 17, wherein, when the bottom surface of the first dummy pad comprises the embossed structure,
wherein the bottom surface of the first dummy pad comprises a lowest surface and a raised surface, and
wherein the raised surface protrudes from the lowest surface in the upward direction.

19. The semiconductor device of claim 17, wherein, when the top surface of the second dummy pad comprises the embossed structure,
wherein the top surface of the second dummy pad comprises a highest surface and a recessed surface, and
wherein the recessed surface is recessed from the highest surface in the downward direction.

20. The semiconductor device of claim 17, wherein a top surface of the first dummy pad and a top surface of the first connection pad have a same shape, and
wherein a bottom surface of the second dummy pad and a bottom surface of the second connection pad have a same shape.
